(19) United States
(12) Patent Application Publication
(10) Pub. No.: US 2025/0374507 A1
(43) Pub. Date: Dec. 4, 2025

(54) SEMICONDUCTOR STRUCTURE WITH IMPLANTED SOURCE/DRAIN STRUCTURE AND METHOD FOR MANUFACTURING THE SAME

(71) Applicant: Taiwan Semiconductor Manufacturing Company, Ltd., Hsinchu (TW)

(72) Inventors: Wei-Ping TSAI, Hsinchu County (TW); Jung-Piao CHIU, Kaohsiung City (TW)

(73) Assignee: Taiwan Semiconductor Manufacturing Company, Ltd., Hsinchu (TW)

(21) Appl. No.: 18/896,664

(22) Filed: Sep. 25, 2024

Related U.S. Application Data
(60) Provisional application No. 63/654,309, filed on May 31, 2024.

(51) Int. Cl. H10B 10/00

(52) U.S. Cl. CPC H10B 10/125

(57) ABSTRACT

Semiconductor structures and method for forming the same are provided. The semiconductor structure includes a first transistor formed in a first well region. The first transistor includes first channel structures, a first source/drain structure, and a first region of a first gate structure wrapping around the first channel structures. The semiconductor structure further includes a second transistor formed in a second well region. The second transistor includes second channel structures, a second source/drain structure, and a second region of the first gate structure wrapping around the second channel structures. In addition, the first well region has a first conductivity type and the second well region has a second conductivity type that is different from the first conductivity type, and the first source/drain structure and the second source/drain structure are both doped with first dopants of the second conductivity type.

### PRIORITY CLAIM AND CROSS-REFERENCE

This application claims priority to U.S. Provisional Application Ser. No. 63/654,309, filed on May 31, 2024, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIG. 1A illustrates a layout of a SRAM cell in accordance with some embodiments.

FIG. 1B illustrates a layout of a logic cell in accordance with some embodiments.

FIGS. 2A-1, 2B-1, and 2C-1 illustrate diagrammatic perspective views of intermediate stages of manufacturing a semiconductor structure in a SRAM cell region in accordance with some embodiments.

FIGS. 2A-2, 2B-2, and 2C-2 illustrate diagrammatic perspective views of intermediate stages of manufacturing the semiconductor structure in a logic cell region 20 in accordance with some embodiments.

FIGS. 3A-1 to 3N-1, 3A-2 to 3N-2, 3A-3 to 3N-3, and 3A-4 to 3N-4 illustrate the cross-sectional views of intermediate stages of manufacturing the semiconductor structure in the SRAM cell region shown along the lines YS_{SD}-YS_{SD}′, YS_{MG}-YS_{MG}′, XS₁-XS₁′, and XS₂-XS₂′ in FIG. 2C-1, respectively, in accordance with some embodiments.

FIGS. 3A-5 to 3N-5 illustrate the cross-sectional views of intermediate stages of manufacturing the semiconductor structure in the logic cell region shown along the lines YL_{SD}-YL_{SD}′ in FIG. 2C-2 in accordance with some embodiments.

FIG. 3J-6 illustrates the position of the mask structure over the layout of the SRAM cell in accordance with some embodiments.

FIG. 3J-7 illustrates the cross-sectional view of the structure shown along line YS_{SD_3J}-YS_{SD_3J}′ in FIG. 3J-6 in accordance with some embodiments.

FIG. 3J-8 illustrates the cross-sectional view of the structure shown along line XS₃-XS₃′ in FIG. 3J-6 in accordance with some embodiments.

FIG. 3J-9 illustrates the position of the mask structure over the layout of the logic cell in accordance with some embodiments.

FIG. 3J-10 illustrates the cross-sectional view of the structure shown along line YL_{MG}-YL_{MG}′ in FIG. 3J-9 in accordance with some embodiments.

FIG. 3J-11 illustrates the top view of the SRAM cell in accordance with some embodiments.

FIG. 3N-6 illustrates the layout of the SRAM cell in accordance with some embodiments.

FIG. 3N-7 illustrates the layout of the logic cell in accordance with some embodiments.

FIG. 3N-8 illustrates the cross-sectional view of the structure shown along line XS₃-XS₃′ in FIG. 3N-6 in accordance with some embodiments.

FIG. 3N-9 illustrates the cross-sectional view of the structure shown along line YL_{MG}-YL_{MG}′ in FIG. 3N-7 in accordance with some embodiments.

FIG. 3N-10 illustrates an enlarged structure of a region R_{3N-1} shown in FIG. 3N-1 in accordance with some embodiments.

FIG. 3N-11 illustrates an enlarged structure of a region R_{3N-5} shown in FIG. 3N-5 in accordance with some embodiments.

FIG. 3N-12 illustrates an enlarged structure of a region R_{3N-3} shown in FIG. 3N-3 in accordance with some embodiments.

FIG. 4A illustrates a position of a mask structure for forming a SRAM cell in accordance with some embodiments.

FIG. 4B illustrates the layout of the SRAM cell in accordance with some embodiments.

FIG. 4C illustrates a cross-sectional view of the SRAM cell along line XS₂-XS₂′ in FIG. 4B in accordance with some embodiments.

FIG. 5A illustrates a layout of a SRAM cell in accordance with some embodiments.

FIG. 5B illustrates a layout of a logic cell in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistors (e.g. nanosheet transistors, nanowire transistors, multi-bridge channel transistors, nano-ribbon FET, and gate all around (GAA) transistors) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

As the feature sizes continue to decrease in semiconductor devices, gate-all-around (GAA) transistors may be adopted to both logic devices and memory devices, such as static random-access memory (SRAM) devices. Generally, channel structures (e.g. nanostructures) in the GAA transistors are manufactured by forming a semiconductor stack including channel layers (e.g. Si layers) and sacrificial layers (e.g. SiGe layers) alternately stacked. The sacrificial layers may be removed so that gate structure formed afterwards may wrap the channel layers.

However, during the formation of the semiconductor devices, Ge in the sacrificial layers may diffuse into the channel layers during the manufacturing processes such as thermal processes. The performance of the resulting devices may therefore be undermined due to the Ge diffusion in the channel layers. Accordingly, in some embodiments of the present disclosure, the sacrificial layers are replaced with dielectric features in a relatively early stage of the manufacturing process (e.g. before the thermal processes are performed). Therefore, the issues of Ge diffusion may be reduced or avoided. In addition, since the channel layers and the dielectric features have relatively high etching selectivity, the size of the channel layers in the resulting devices can be better controlled, and the performance may therefore be improved.

On the other hand, when the sacrificial layers are replaced with the dielectric features, the performance of the PMOS transistor may become too strong due to the stress change (e.g. tensile stress provided by the sacrificial layers no longer exist) in some cases. For example, pull-up transistors (PU) in the SRAM devices may become too strong (e.g. over 30% overshoot) when the dielectric features are applied, and Vmin degradation may therefore occurs. Accordingly, in some embodiments, an implantation process is performed on the source/drain structures of the pull-up transistors, so that the overshoot and unbalance issues may be reduced. Furthermore, in some other cases, ring oscillator (RO) unbalance at NFET and PFET may also happen, resulting in lower power efficiency of the resulting devices.

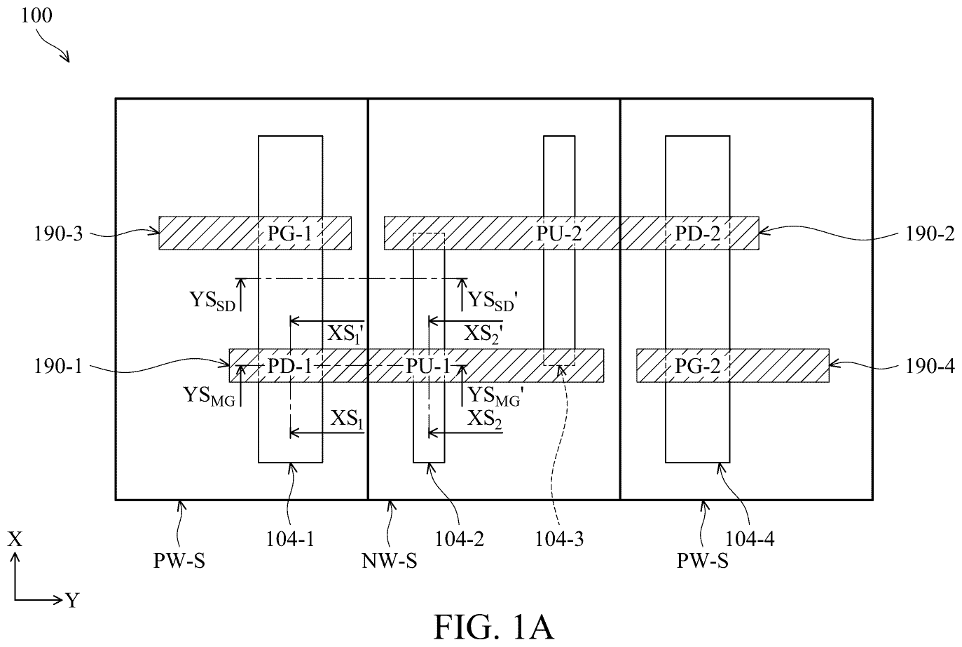

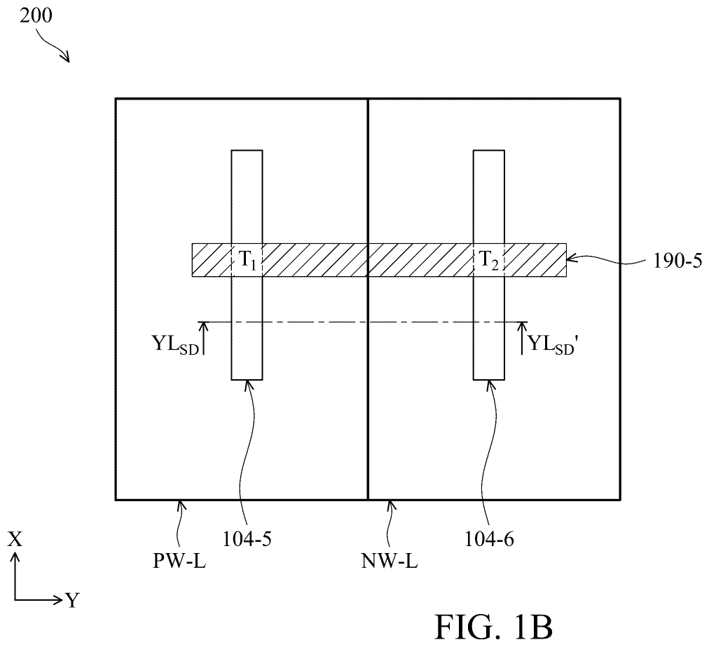

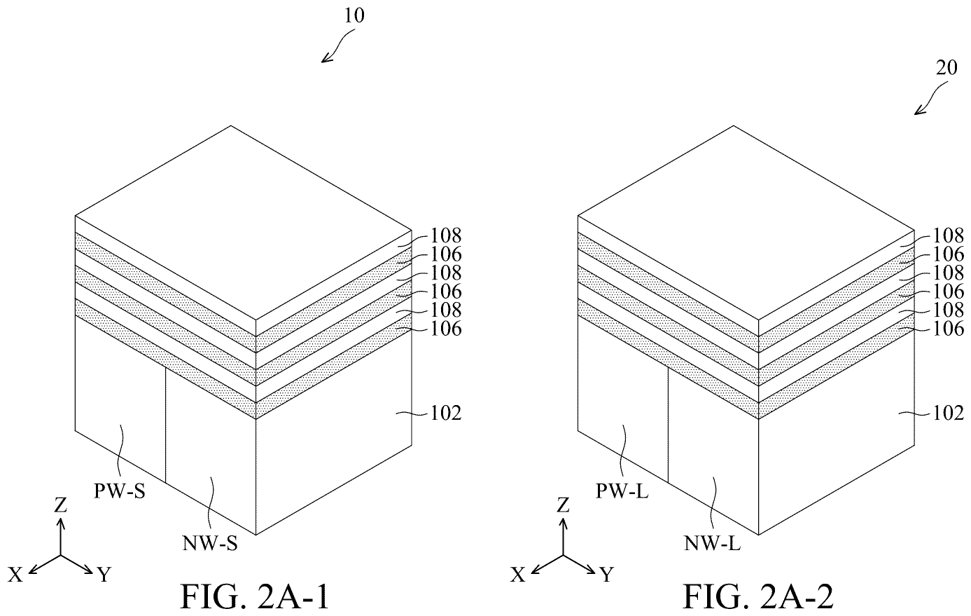

FIG. 1A illustrates a layout of a SRAM cell 100 in accordance with some embodiments. The SRAM cell 100 includes active regions 104 (including 104-1, 104-1, 104-3, and 104-4) and gate structures 190 (including 190-1, 190-2, 190-3, and 190-4) in accordance with some embodiments. The active regions 104 may also be called as fin structures, nanostructures, or channel structures. The active region 104-1 is formed in a p-type well PW_S, the active regions 104-2 and 104-3 are formed in an n-type well NW_S, and the active region 104_4 is formed in another p-type well PW_S in accordance with some embodiments. The n-type well NW_S is arranged between the two p-type wells PW_S in accordance with some embodiments.

In some embodiments, the SRAM cell 100 includes six functional transistors, including pass-gate transistors PG-1 and PG-2, pull-down transistors PD-1 and PD-2, and pull-up transistors PU-1 and PU-2. In some embodiments, the pass-gate transistors PG-1 and PG-2 and the pull-down transistors PD-1 and PD-2 are NMOS transistors, and the pull-up transistors PU-1 and PU-2 are PMOS transistors.

More specifically, the pass-gate transistor PG-1 includes the active region 104-1 and the gate structure 190-3 in accordance with some embodiments. The pull-down transistor PD-1 includes the active region 104-1 and the gate structure 190-1 in accordance with some embodiments. The pass-gate transistor PG-2 includes the active region 104-4 and the gate structure 190-4 in accordance with some embodiments. The pull-down transistor PD-2 includes the active region 104-4 and the gate structure 190-2 in accordance with some embodiments. The pull-up transistor PU-1 includes the active region 104-2 and the gate structure 190-1 in accordance with some embodiments. The pull-up transistor PU-2 includes the active region 104-3 and the gate structure 190-2. In addition, no functional transistors are formed at the cross point of the active regions 104-2 and the gate structure 190-2 and at the cross point of the active regions 104-3 and the gate structure 190-1.

FIG. 1B illustrates a layout of a logic cell 200 in accordance with some embodiments. The logic cell 200 includes active regions (including 104-5 and 104-6) and a gate structure 190-5 in accordance with some embodiments. The active region 104-5 is formed in a p-type well PW_L, the active region 104-6 is formed in an n-type well NW_L in accordance with some embodiments. In some embodiments, the logic cell 200 includes two functional transistors, T1 and T2. The transistor T1 includes the active region 104-5 and the gate structure 190-5, and the transistor T2 includes the active region 104-6 and the gate structure 190-5.

A semiconductor device may include both the SRAM cell 100 and the logic cell 200, and the transistors in both the SRAM cell 100 and the logic cell 200 include nanostructures. In addition, although one SRAM cell 100 and one logic cell 200 are shown, the semiconductor device may include numbers of the SRAM cells 100 and numbers of the logic cells 200. The formation of the SRAM cell 100 and the logic cell 200 may include using dielectric features as interposers between the channel structures, and the manufacturing processes are described in more details below.

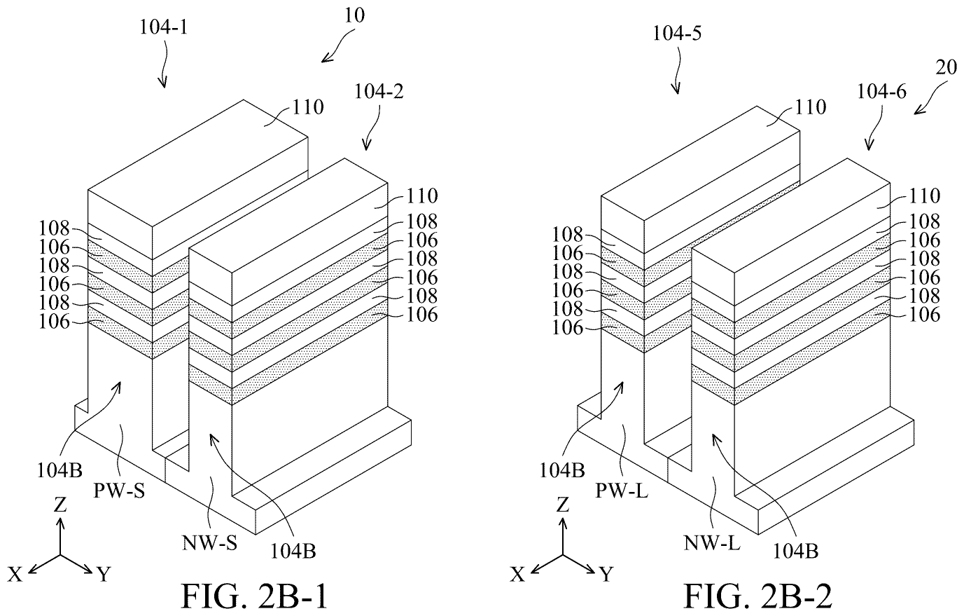

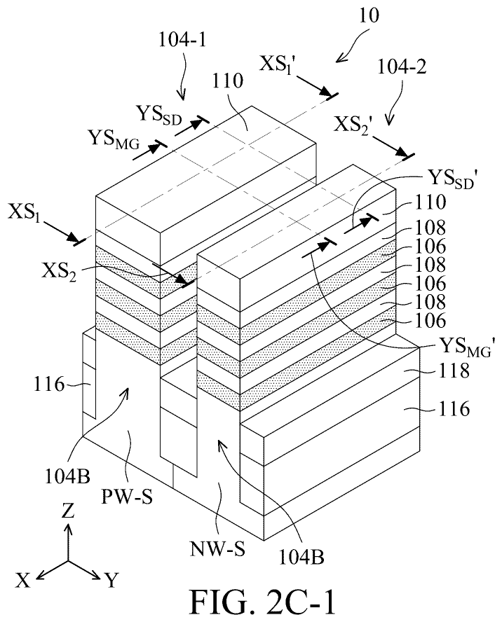

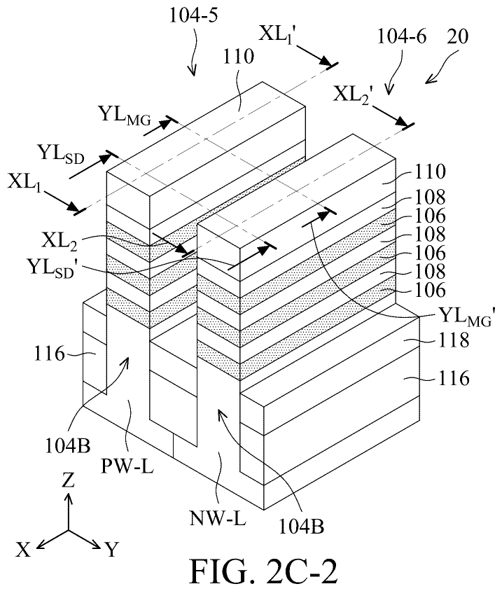

FIGS. 2A-1, 2B-1, and 2C-1 illustrate diagrammatic perspective views of intermediate stages of manufacturing a semiconductor structure in a SRAM cell region 10 in accordance with some embodiments. FIGS. 2A-2, 2B-2, and 2C-2 illustrate diagrammatic perspective views of intermediate stages of manufacturing the semiconductor structure in a logic cell region 20 in accordance with some embodiments.

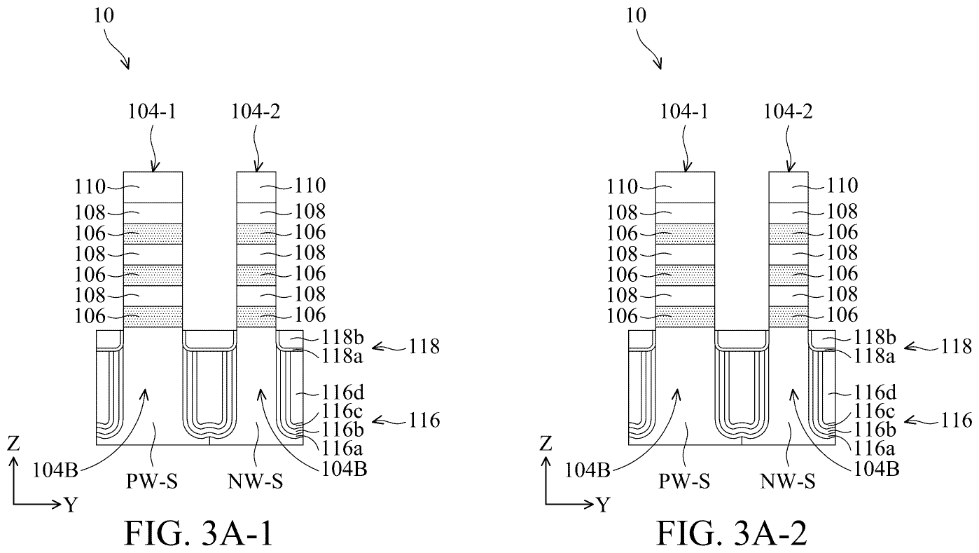

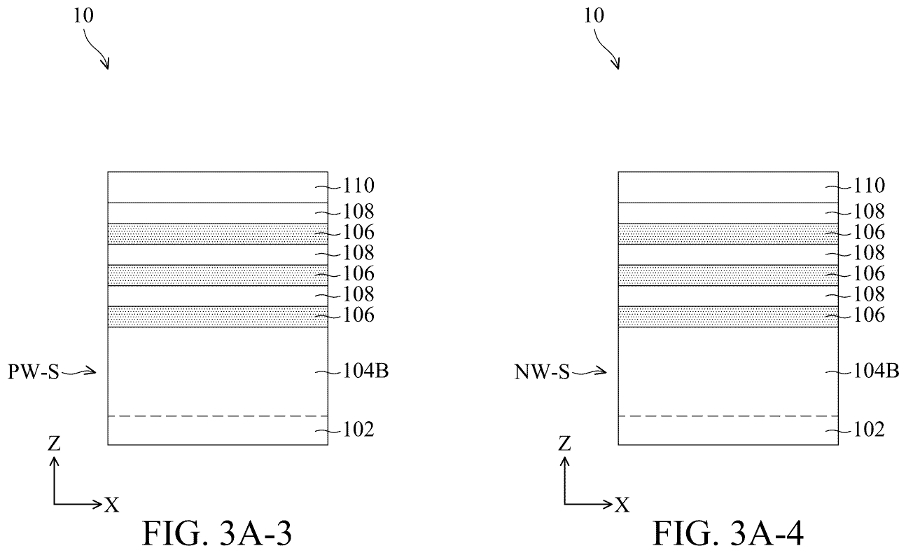

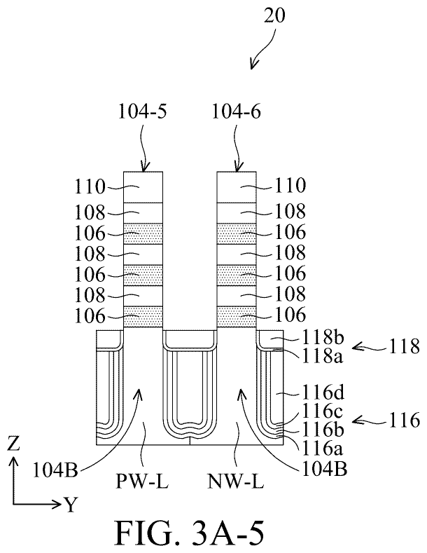

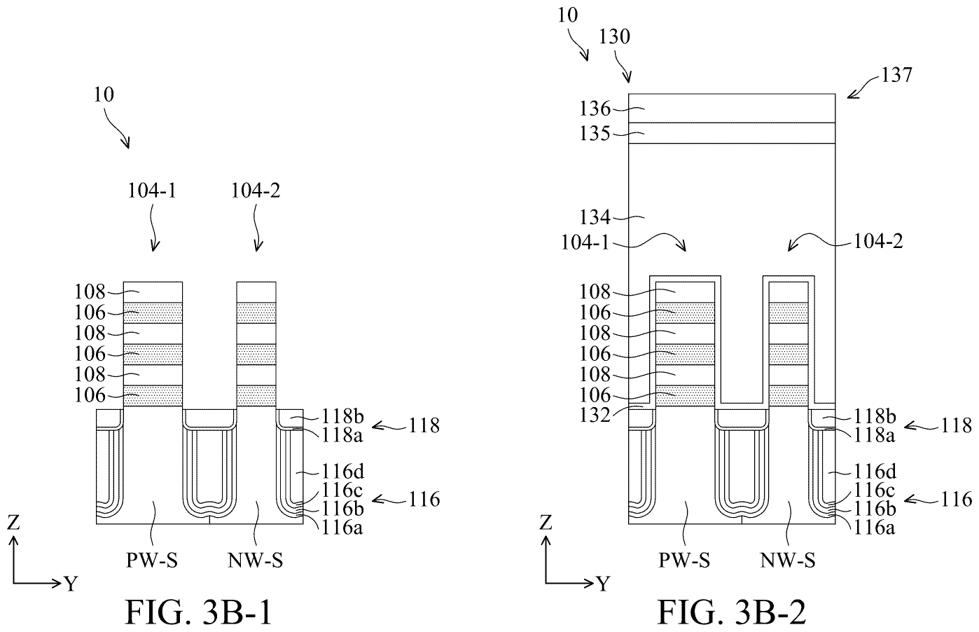

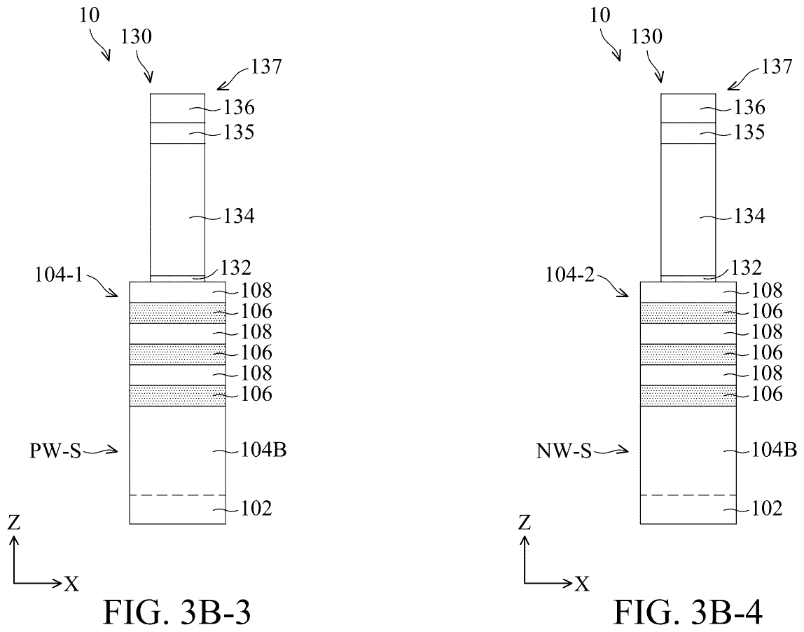

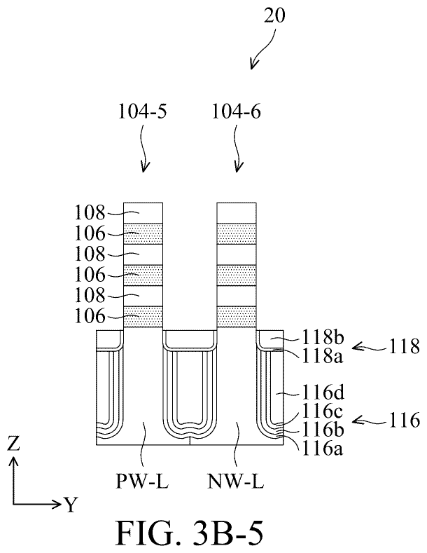

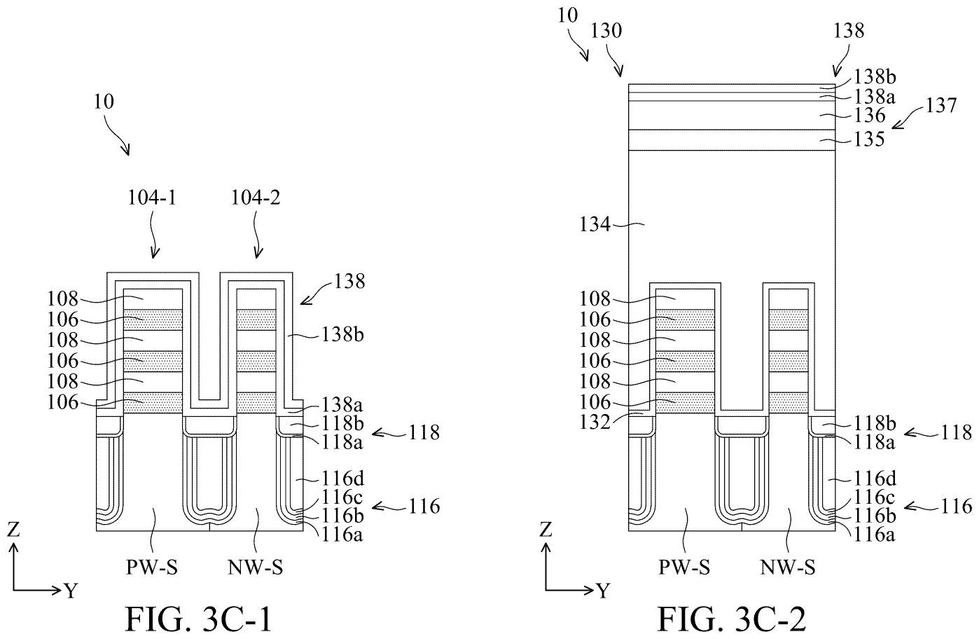

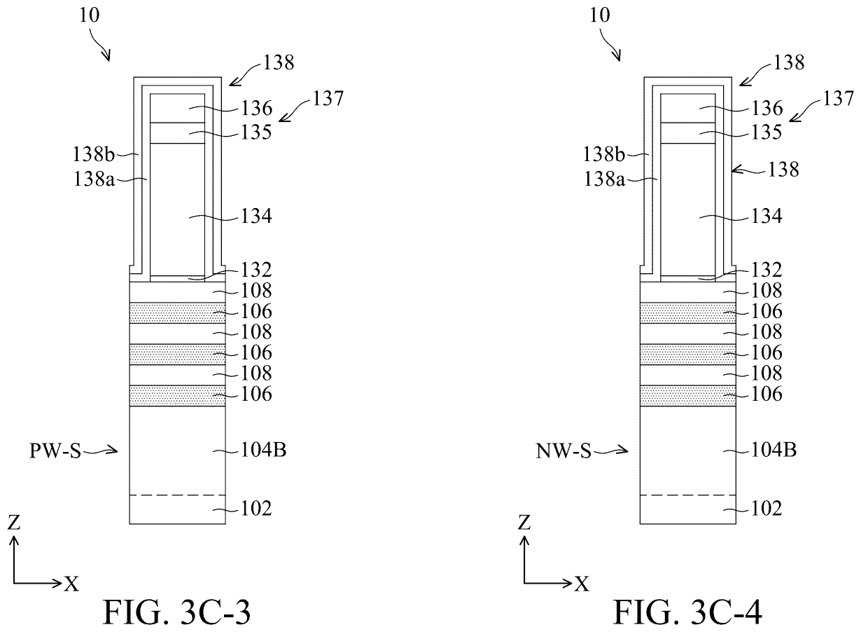

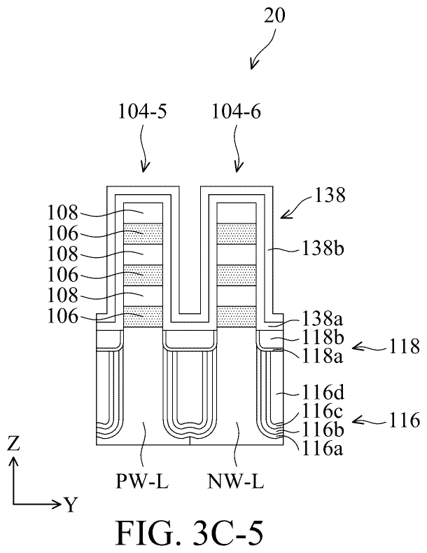

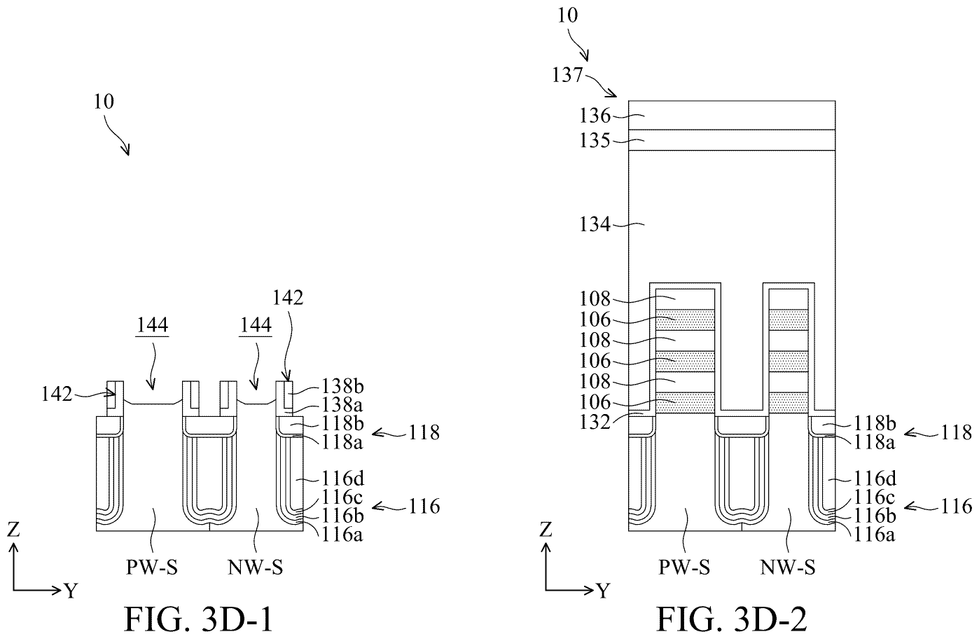

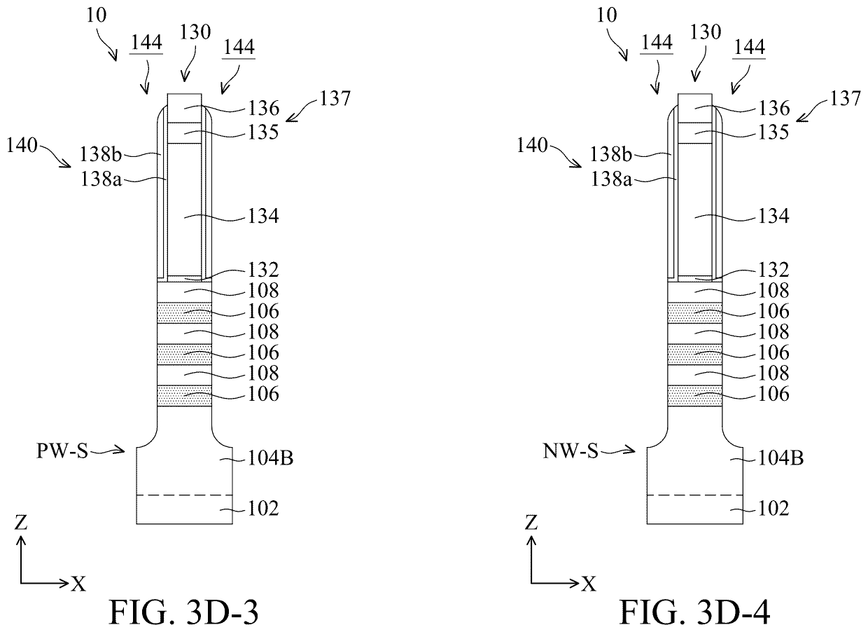

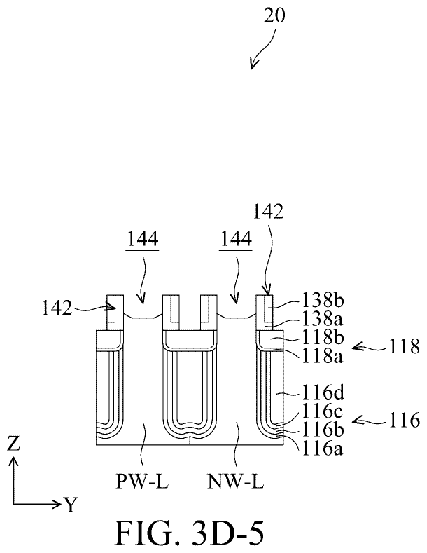

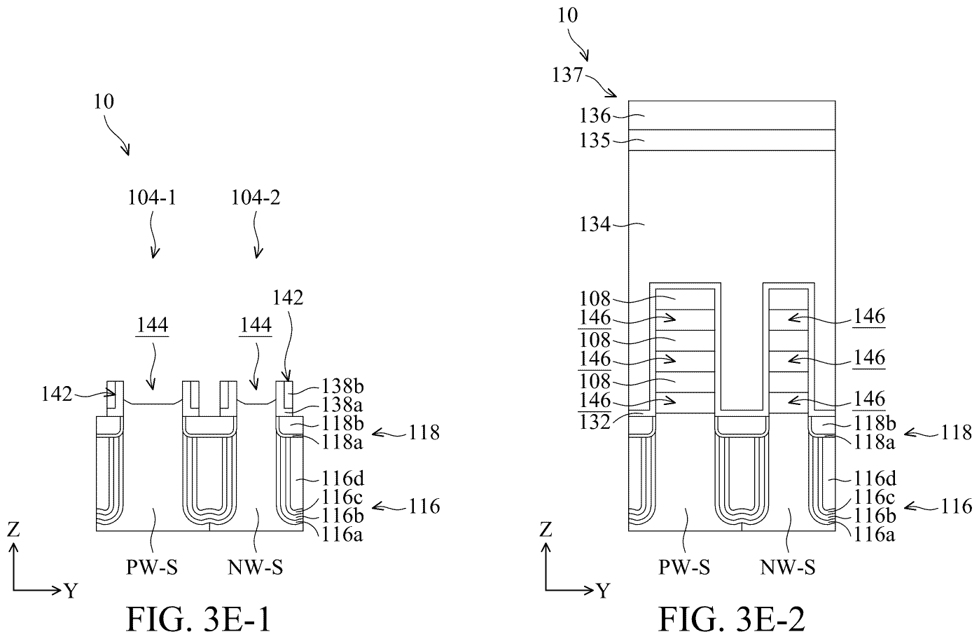

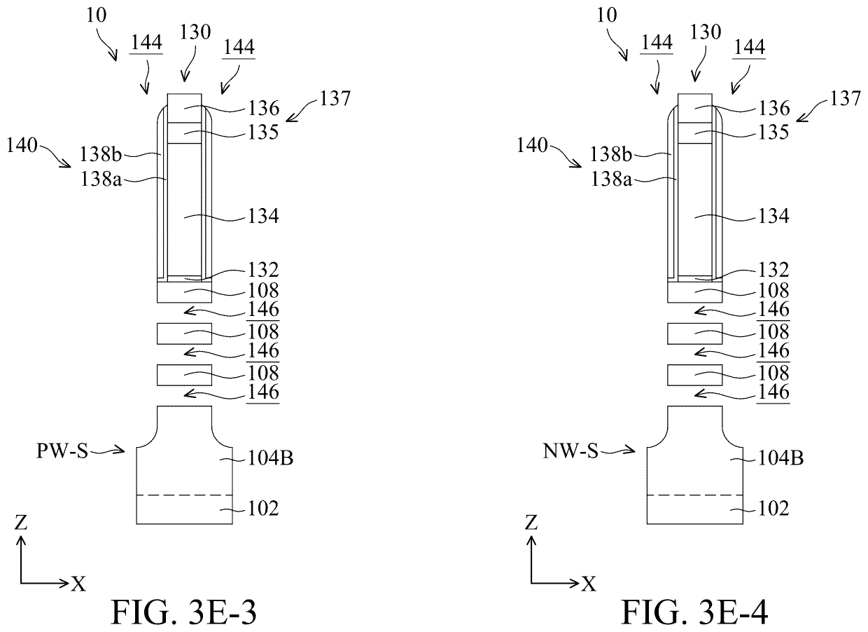

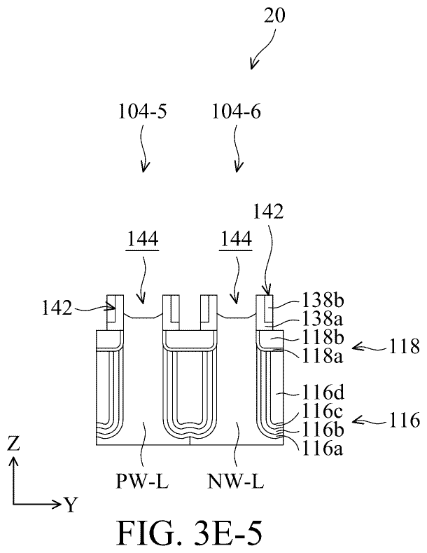

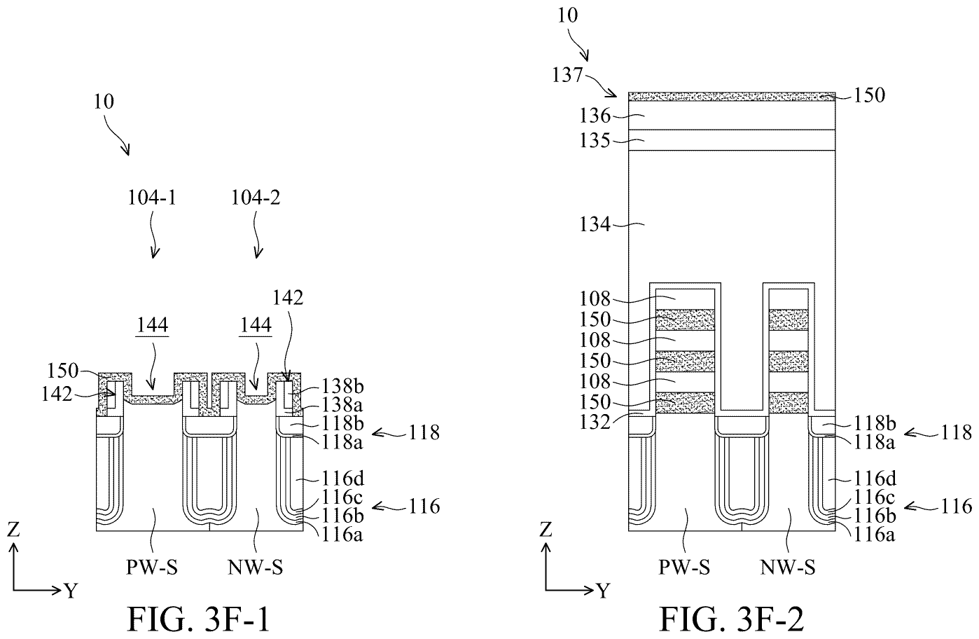

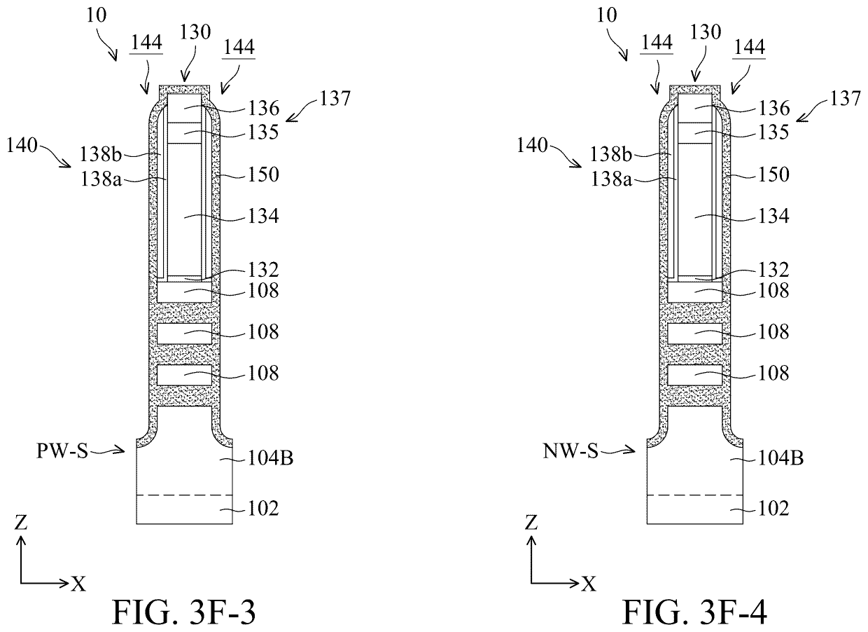

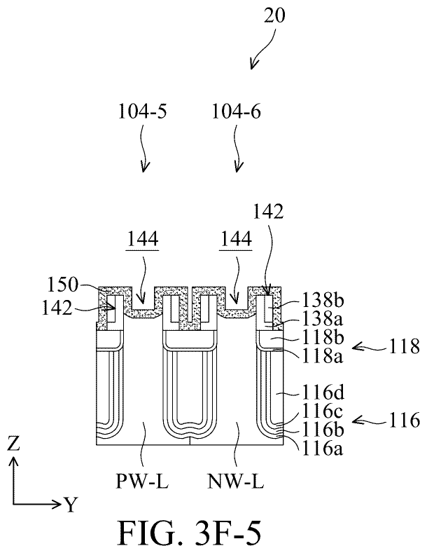

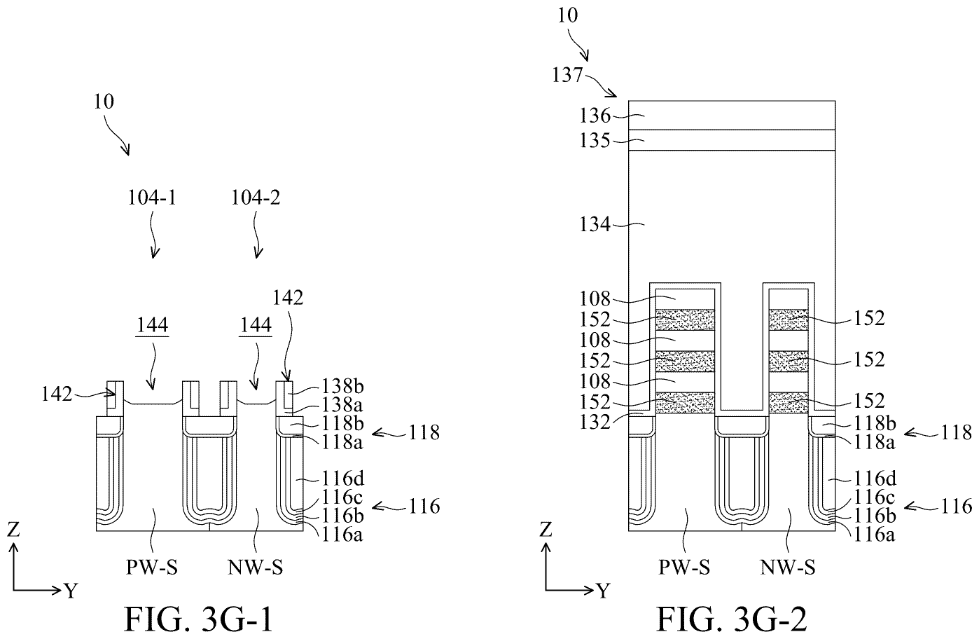

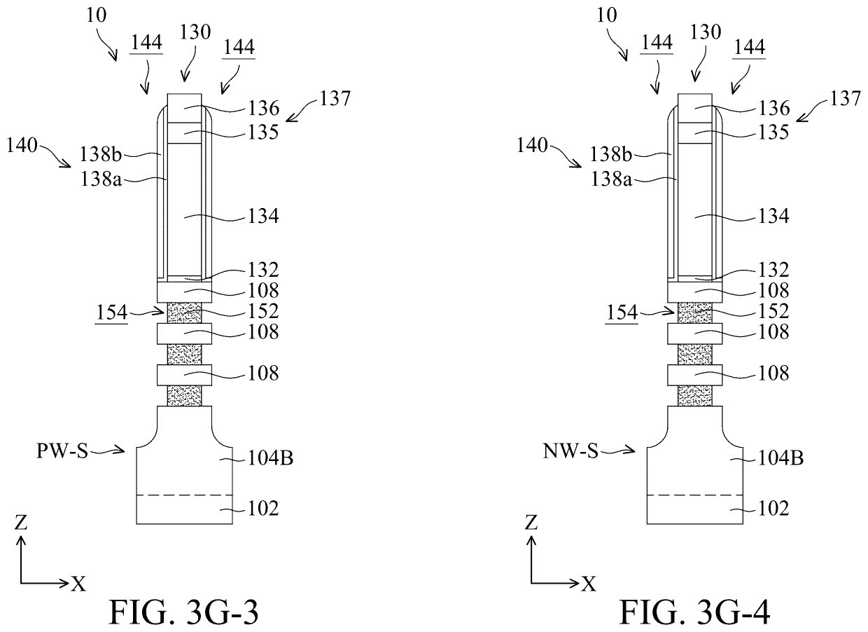

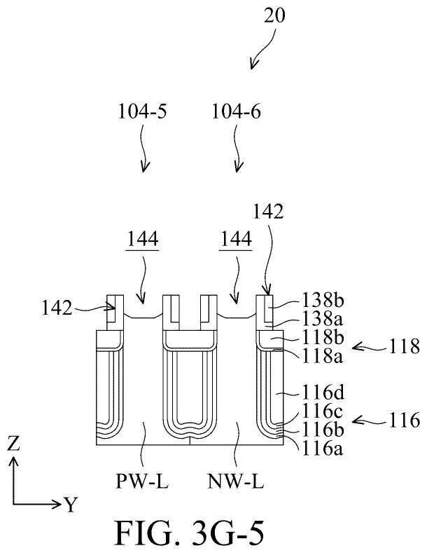

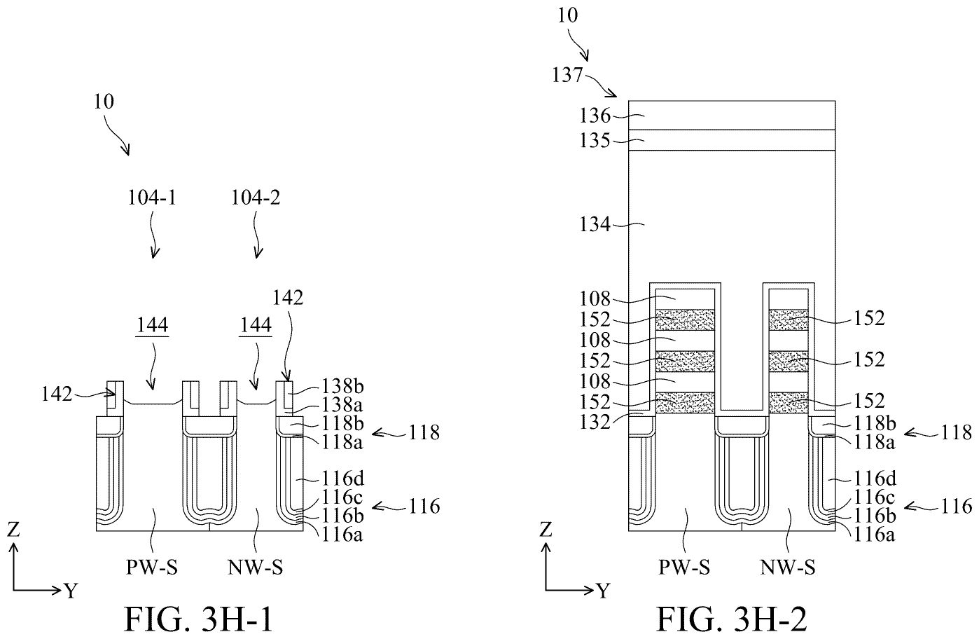

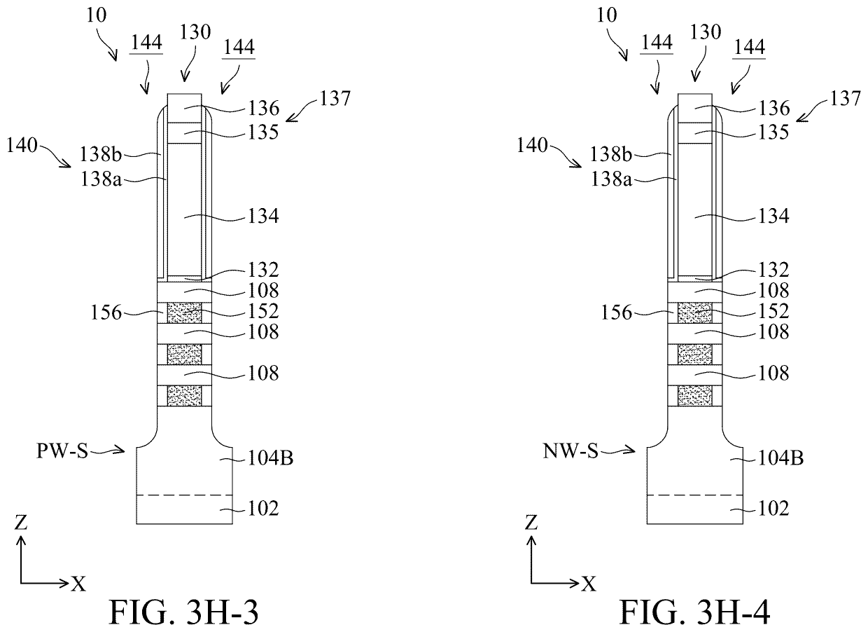

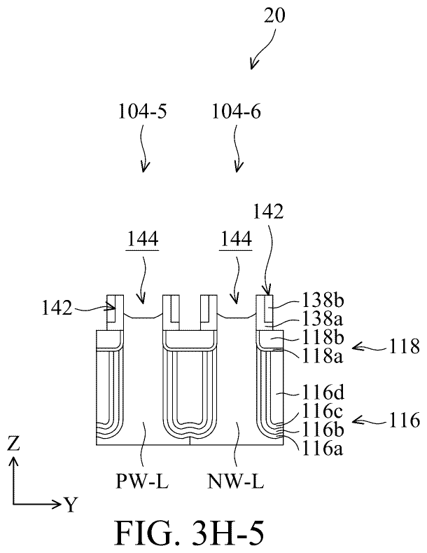

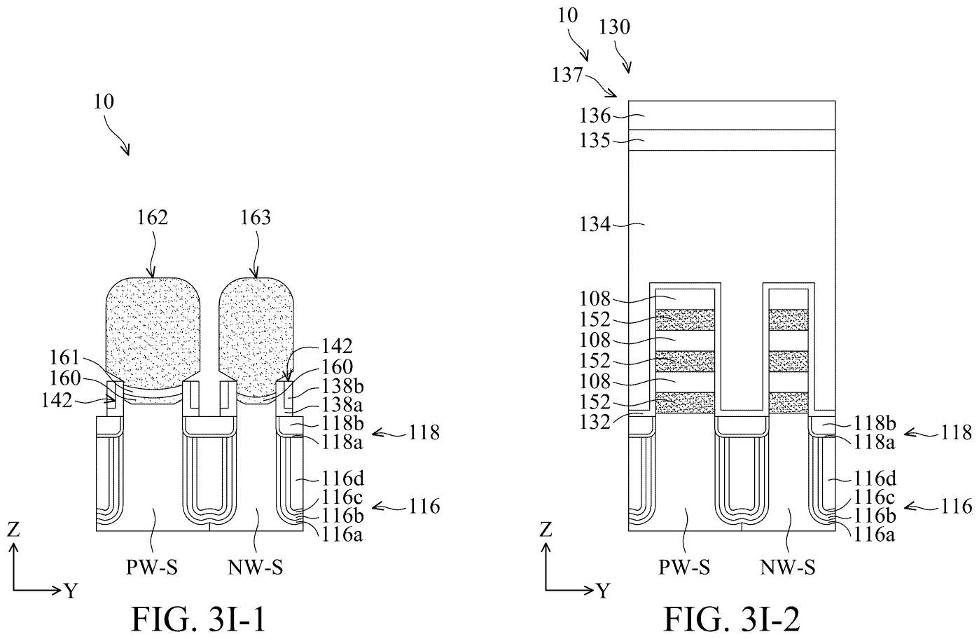

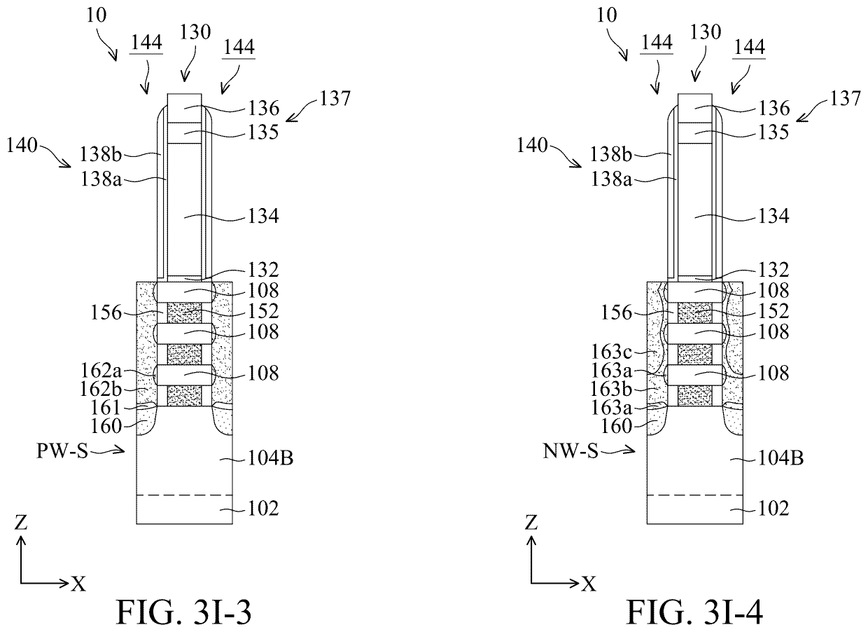

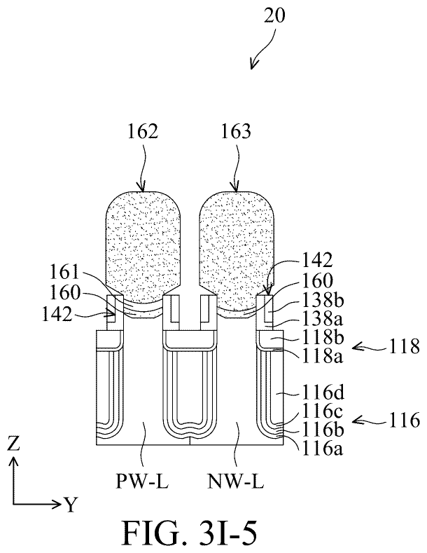

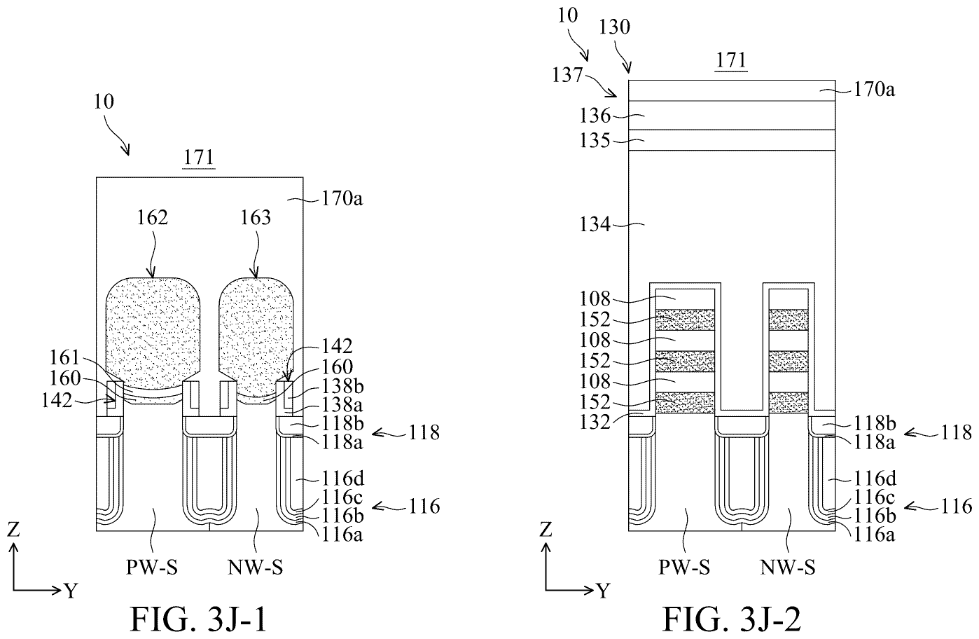

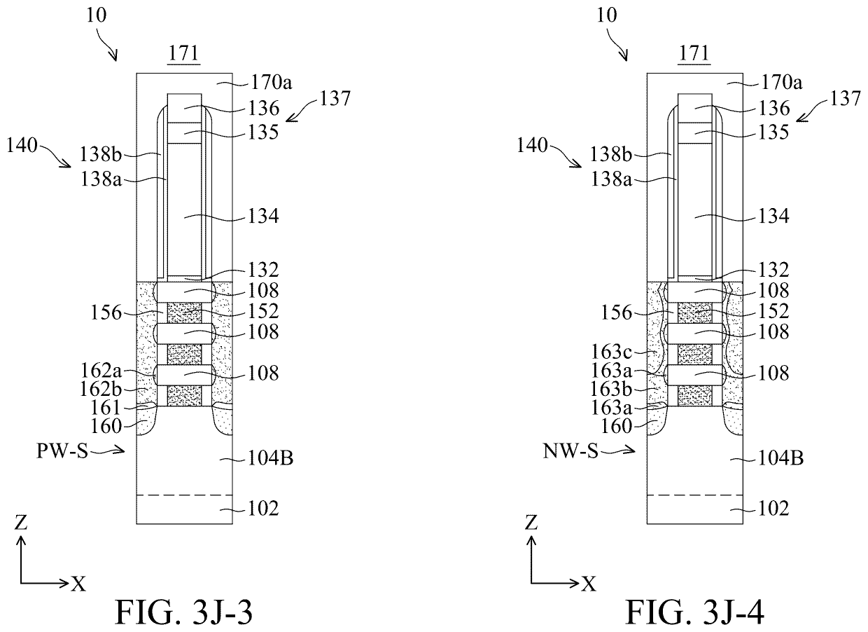

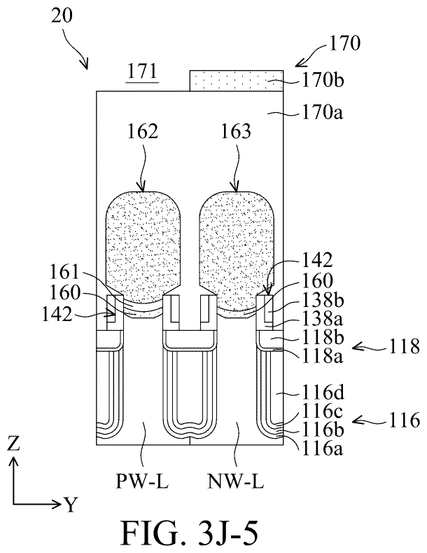

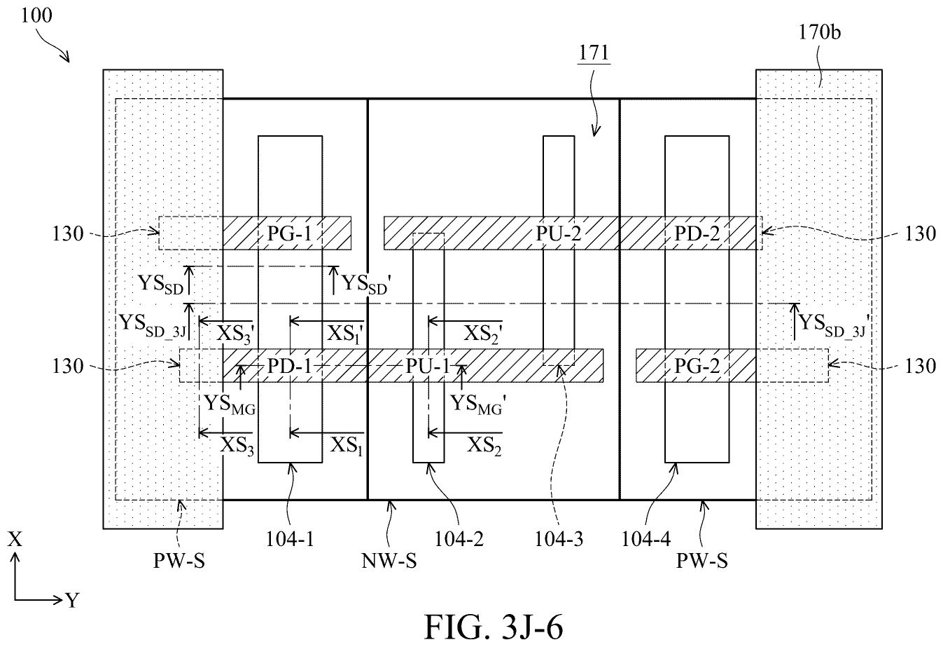

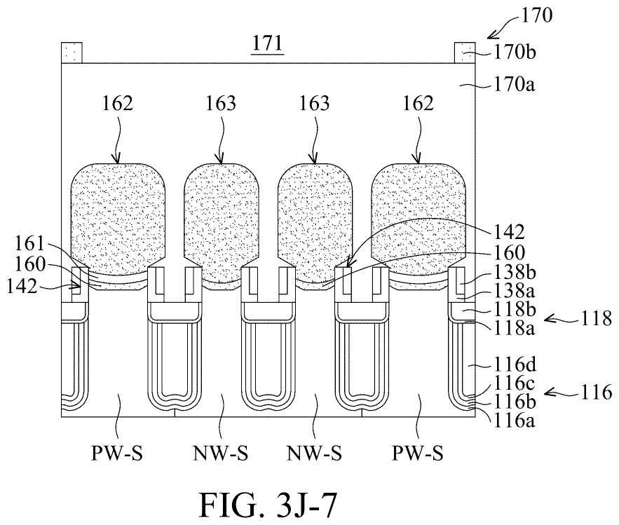

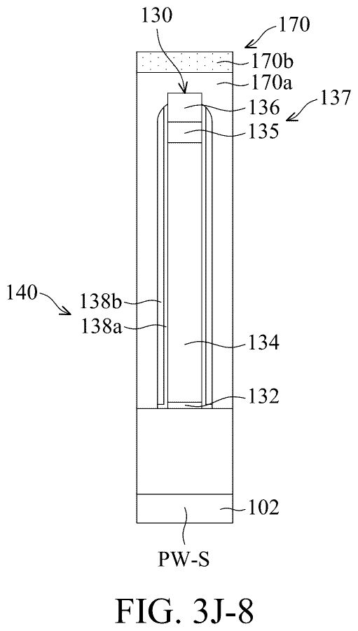

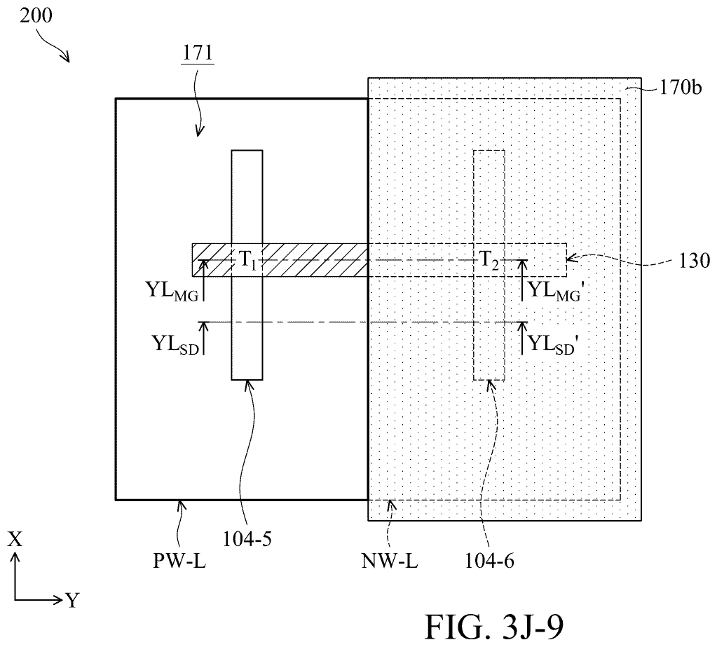

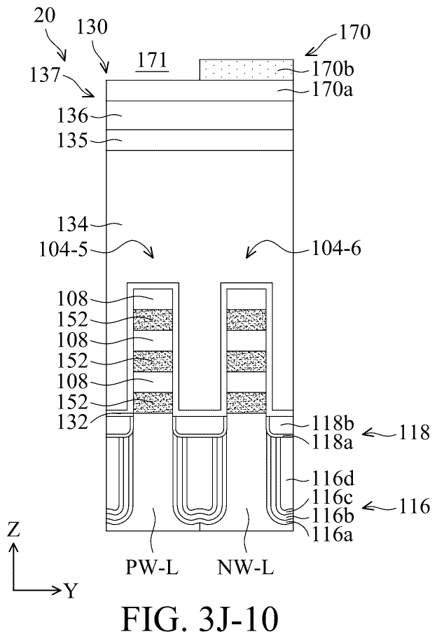

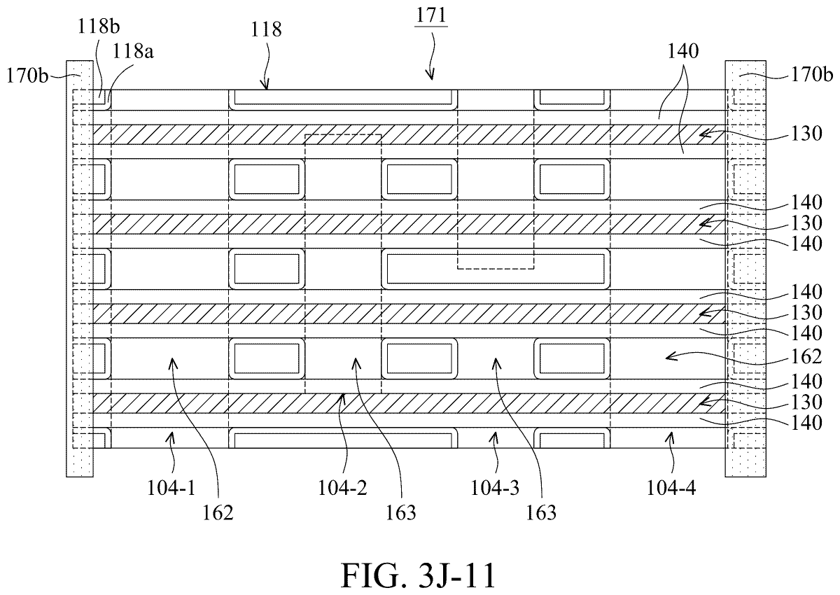

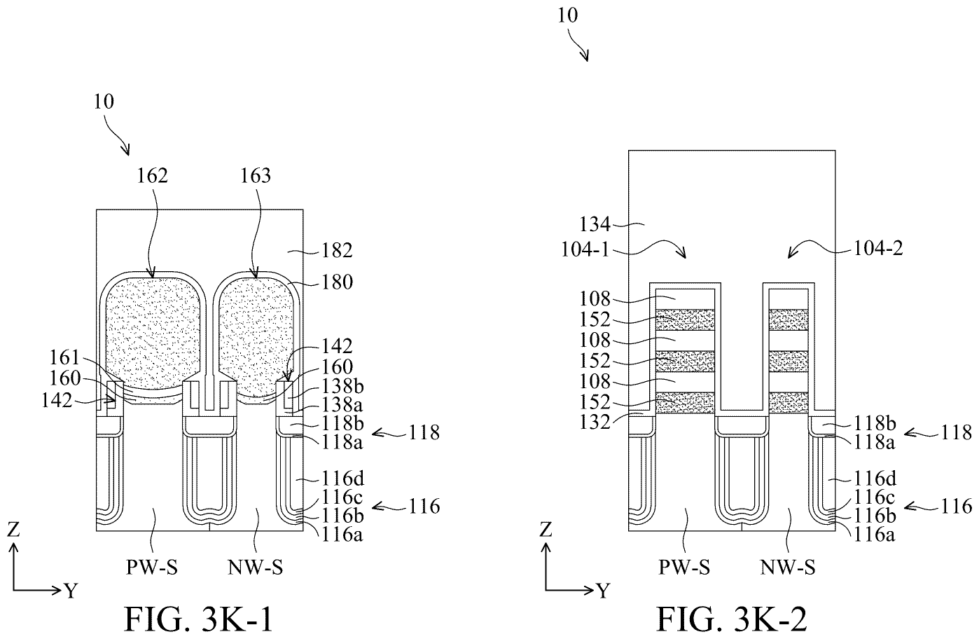

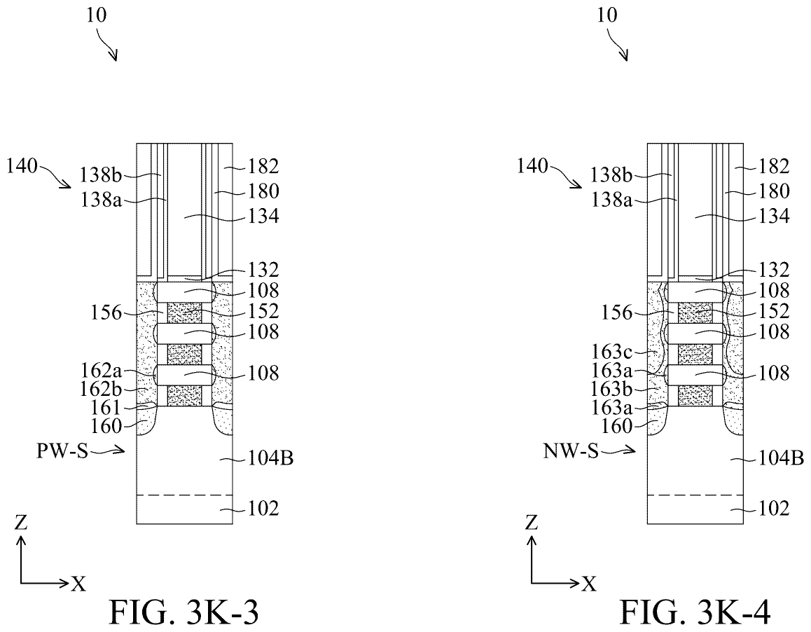

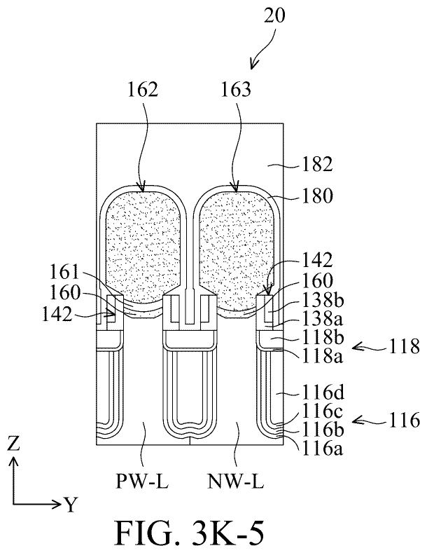

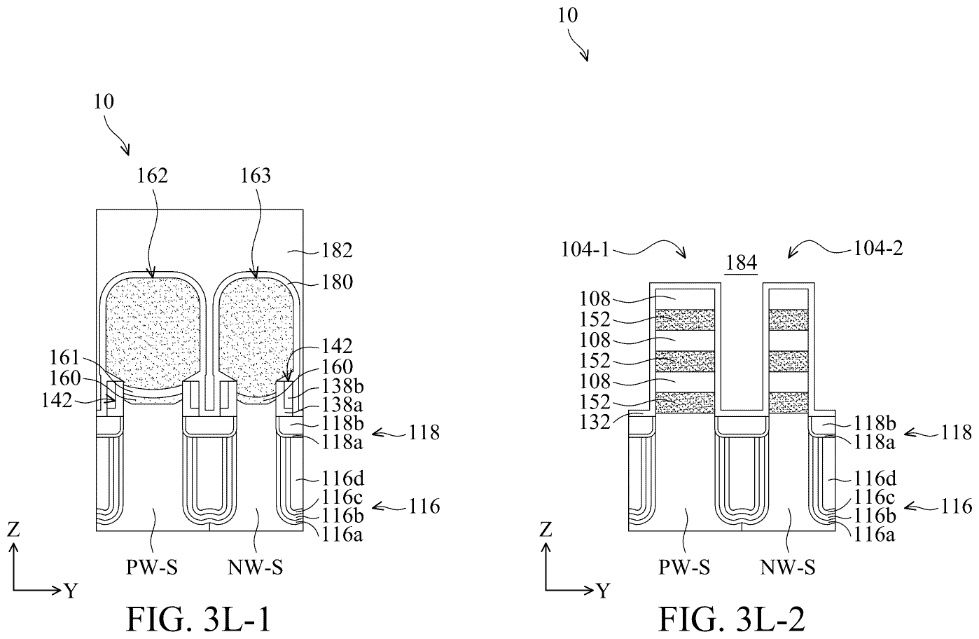

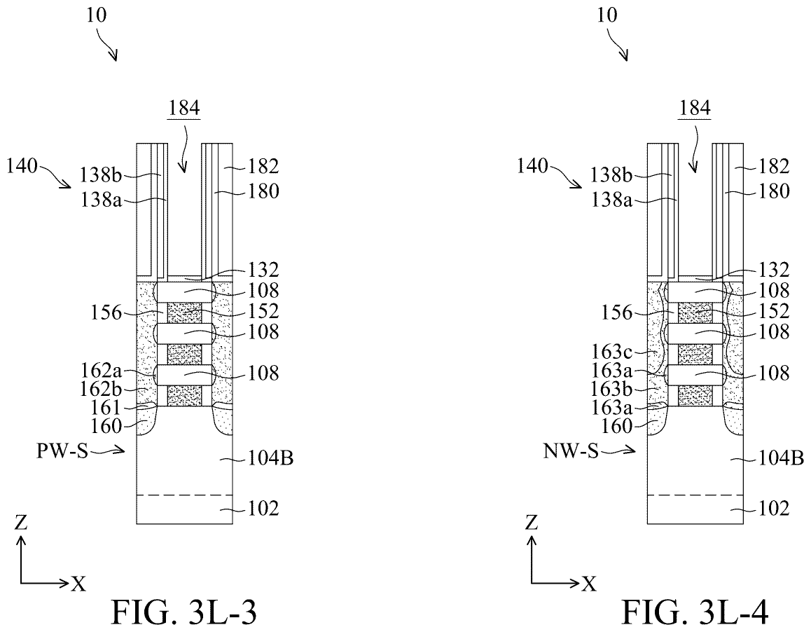

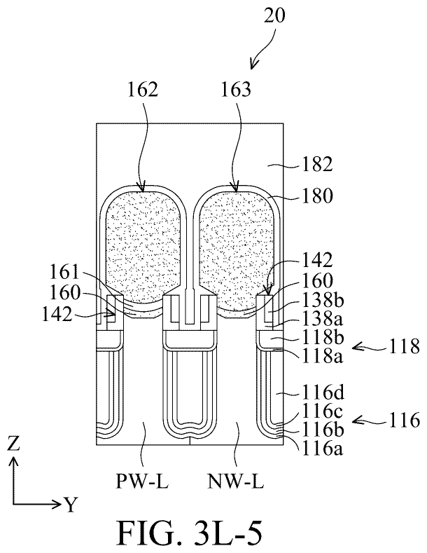

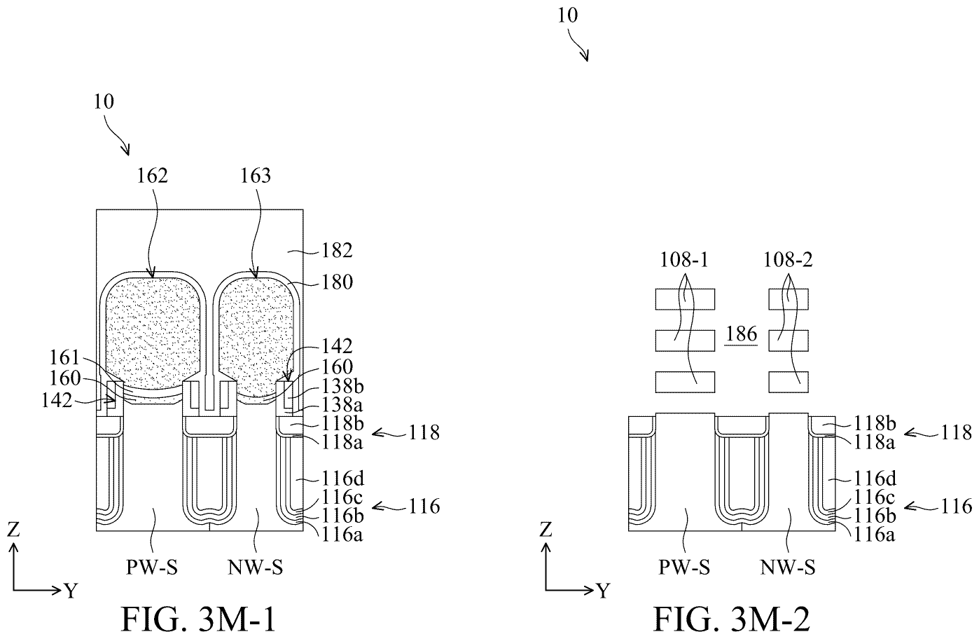

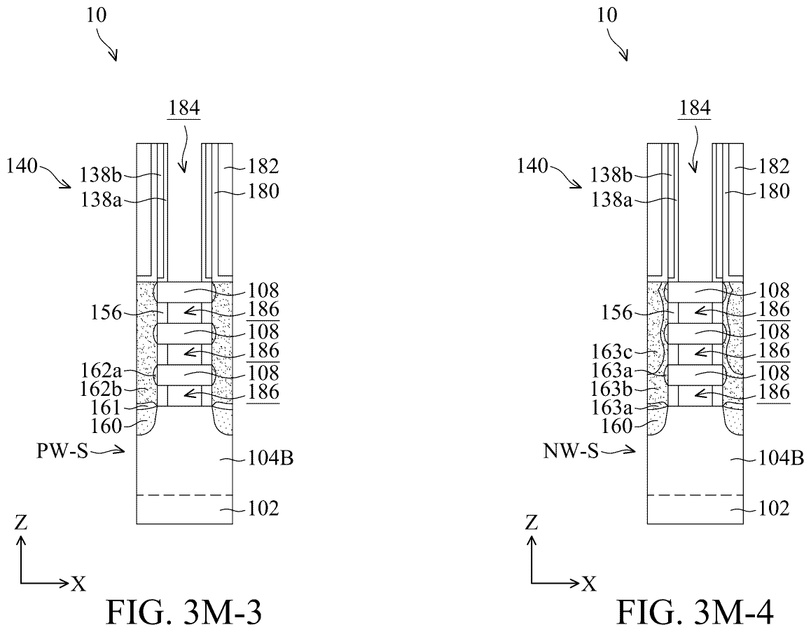

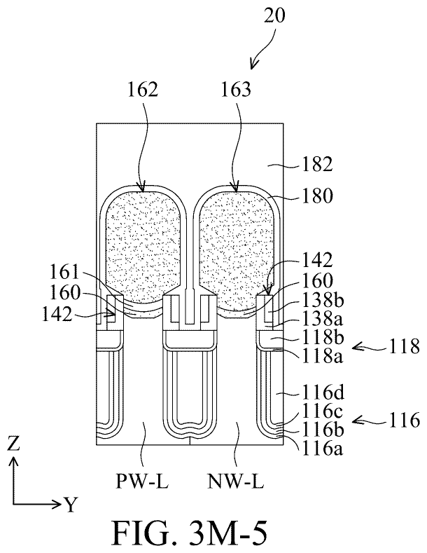

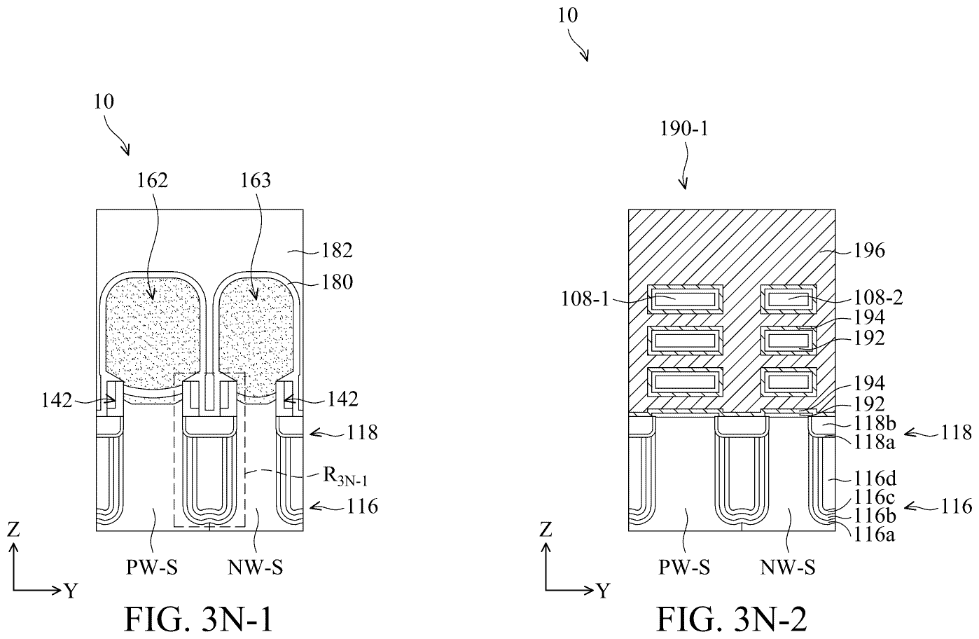

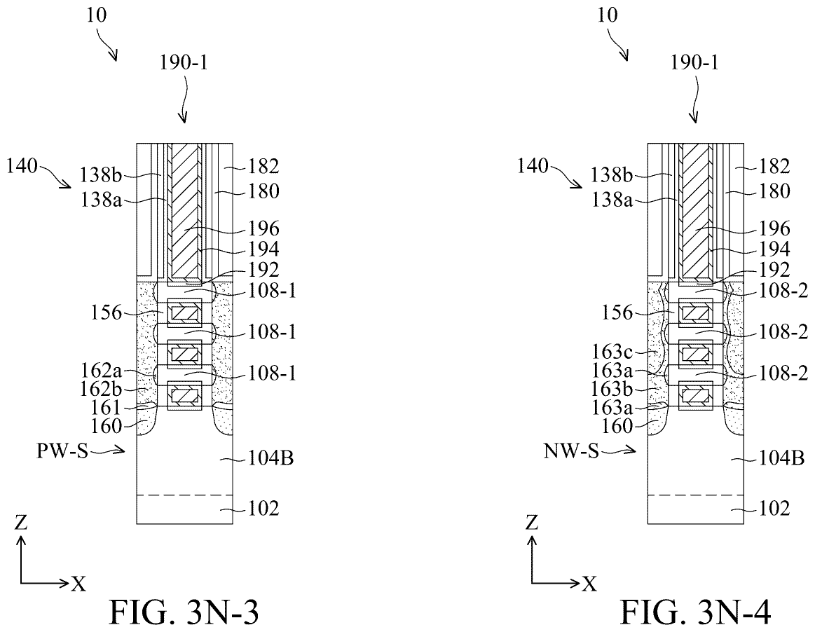

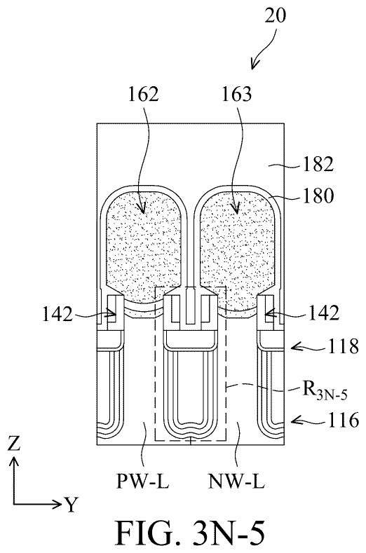

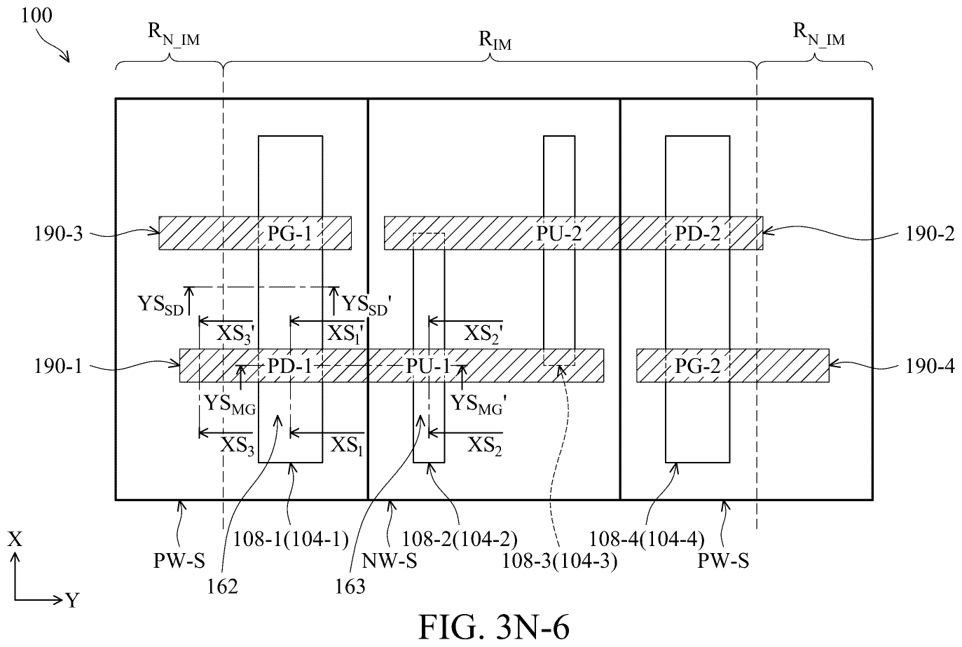

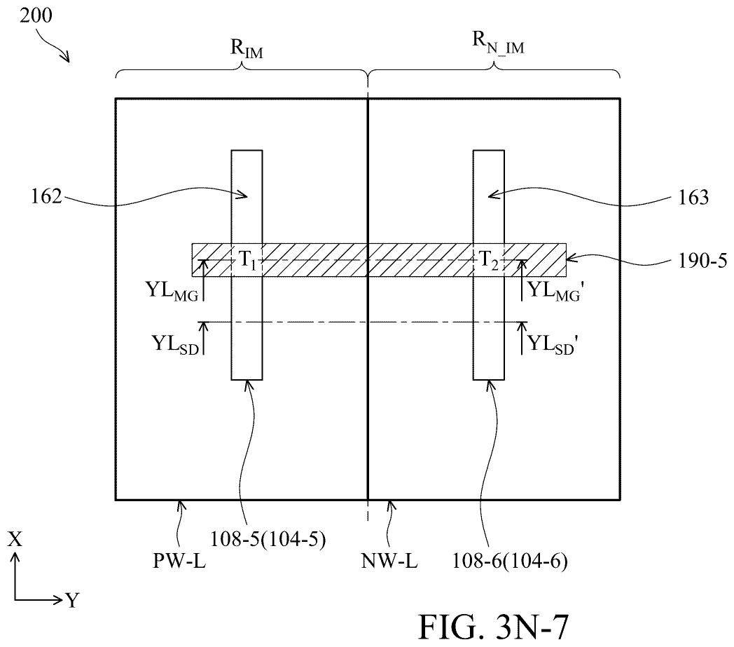

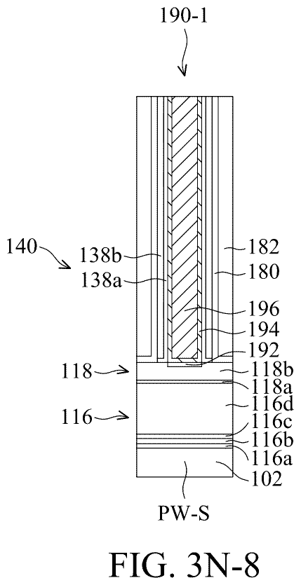

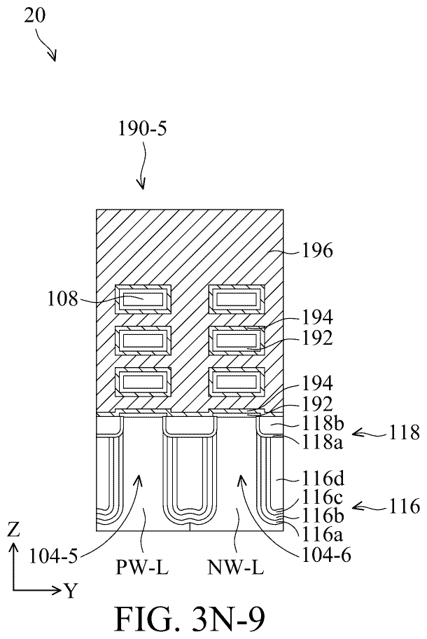

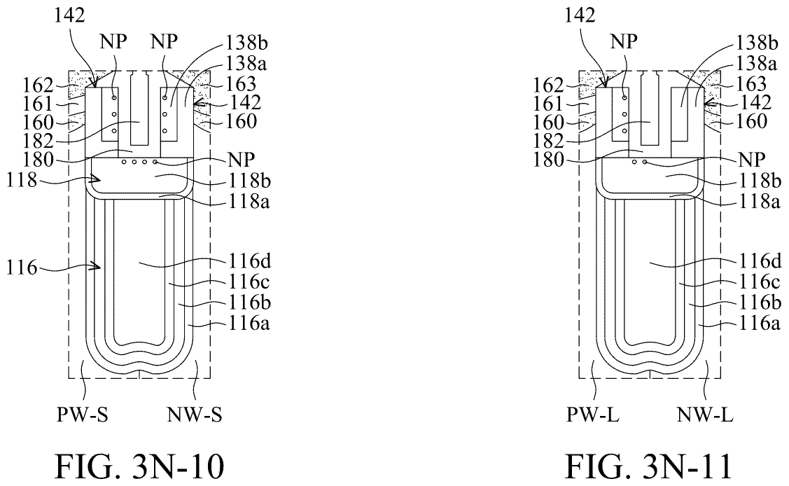

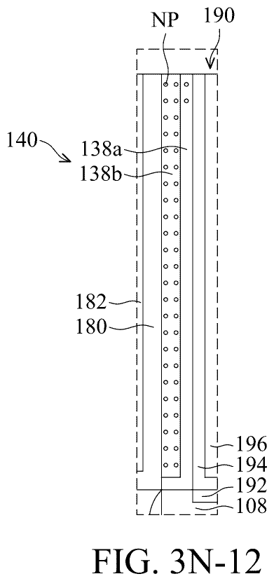

FIGS. 3A-1 to 3N-1, 3A-2 to 3N-2, 3A-3 to 3N-3, and 3A-4 to 3N-4 illustrate the cross-sectional views of intermediate stages of manufacturing the semiconductor structure in the SRAM cell region 10 shown along the lines YS_{SD}-YS_{SD}′ (i.e. in Y direction), YS_{MG}-YS_{MG}′ (i.e. in Y direction), XS₁-XS₁′ (i.e. in X direction), and XS₂-XS₂′ (i.e. in X direction) in FIG. 2C-1, respectively, in accordance with some embodiments. FIGS. 3A-5 to 3N-5 illustrate the cross-sectional views of intermediate stages of manufacturing the semiconductor structure in the logic cell region 20 shown along the lines YL_{SD}-YL_{SD}′ (i.e. in Y direction) in FIG. 2C-2 in accordance with some embodiments.

More specifically, FIGS. 3A-1, 3A-2, 3A-3, and 3A-4 illustrate the cross-sectional views of the intermediate stages of the semiconductor structure in the SRAM cell region 10 shown in FIG. 2C-1, and FIGS. 3B-1 to 3N-1, 3B-2 to 3N-2, 2B-3 to 2N-3, and 3B-4 to 3N-4 illustrate the cross-sectional views of the intermediate stages of manufacturing the semiconductor structure in the SRAM cell region 10 afterwards in accordance with some embodiments. Similarly, FIGS. 3A-5 illustrates the cross-sectional view of the intermediate stage of the semiconductor structure in the logic cell region 20 shown in FIG. 2C-2, and FIGS. 3B-5 to 3N-5 illustrate the cross-sectional views of the intermediate stages of manufacturing the semiconductor structure in the logic cell region 20 afterwards in accordance with some embodiments.

Well regions PW_S and NW-S are formed in a substrate 102 in the SRAM cell region 10, and well regions PW_L and NW_L are formed in the substrate 102 in the logic cell region 20 in accordance with some embodiments. After the cell regions PW_S, NW-S, PW_L, and NW_L are formed, a semiconductor stack including first semiconductor material layers 106 and second semiconductor material layers 108 is formed over both the SRAM cell region 10 and the logic cell region 20 of the substrate 102, as shown in FIGS. 2A-1 and 2A-2 in accordance with some embodiments.

The well regions PW-S and NW-S may be formed next to each other, and the well regions PW-L and NW-L may be formed next to each other in accordance with some embodiments. In some embodiments, the well regions PW_S and PW L are P-type well regions, and N-type transistors are formed over the well regions PW_S and PW_L. In some embodiments, the well regions NW_S and NW_L are N-type well regions, and P-type transistors are formed over the well regions NW_S and NW_L.

For a better understanding of the semiconductor structure, the X-Y-Z coordinate reference is provided in the figures of the present disclosure. The X-axis and the Y-axis are generally orientated along the lateral (or horizontal) direction that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102 to form the semiconductor stack. The first semiconductor material layers 106 may also be called as sacrificial semiconductor layers since they will be removed afterwards. The second semiconductor material layers 108 may also be called as channel layers, since they will be function as the channel regions in the resulting transistors. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. In some embodiments, the Ge concentration in the first semiconductor material layers 106 is in a range from about 35 atm % to about 50 atm %.

It should be noted that although three first semiconductor material layers 106 and three second semiconductor material layers 108 are shown in FIG. 2A-1 and FIG. 2A-2, the semiconductor stack may include less or more of the first semiconductor material layers 106 and the second semiconductor material layers 108 alternately stacked. For example, the semiconductor stack may include two to five of the first semiconductor material layers 106 and two to five of the second semiconductor material layers 108.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as the semiconductor stack over the substrate 102, the semiconductor stack is patterned to form fin structures 104, including fin structures 104-1, 104-2, 104-5, and 104-6, as shown in FIGS. 2B-1 and 2B-2 in accordance with some embodiments. Although not shown in FIG. 2B-1, the fin structures (i.e. active region) 104-3 and 104-4 shown in FIG. 1A may also be formed in the following processes. The fin structures 104-1 to 104-6 may also be called as active regions. As shown in FIGS. 1A and 2B-1, the fin structure 104-1 is wider than the fin structure 104-2 in Y direction in accordance with some embodiments. In some embodiments, a ratio of the width of the fin structure 104-1 to the width of the fin structure 104-2 in Y direction is in a range from about 1 to about 4.

The fin structures 104 may extend lengthwise in X direction, as shown in FIGS. 1A and 1B in accordance with some embodiments. In some embodiments, the patterning process includes forming a mask structure 110 over the semiconductor material stack and etching the semiconductor material stack and the underlying substrate 102 through the mask structure 110. In some embodiments, the mask structure 110 is a multilayer structure including a pad oxide layer and a nitride layer formed over the pad oxide layer. The pad oxide layer may be made of silicon oxide, which is formed by thermal oxidation or CVD, and the nitride layer may be made of silicon nitride, which is formed by CVD, such as LPCVD or plasma-enhanced CVD (PECVD). In some embodiments, the fin structures 104 include base fin structures 104B and the semiconductor stacks, including the first semiconductor material layers 106 and the second semiconductor material layers 108, formed over the base fin structures 104B.

After the fin structures 104 are formed, an isolation structure 116 is formed around the fin structures 104 and a mask structure 118 is formed over the isolation structure 116, as shown in FIGS. 2C-1, 2C-2, 3A-1, 3A-2, 3A-3, 3A-4, and 3A-5 in accordance with some embodiments. The isolation structure 116 is configured to electrically isolate active regions (e.g. the fin structures 104-1 to 104-6) of the semiconductor structure and is also referred to as shallow trench isolation (STI) feature in accordance with some embodiments.

The isolation structure 116 may include multiple layers, although they are not shown in FIG. 2C-1. In some embodiments, the isolation structure 116 includes a first lining layer 116a, a second lining layer 116b, a third lining layer 116c, and a first bulk layer 116d. In some embodiments, the first lining layer 116a extends conformally along the fin structures 104 and the substrate 102, and the second lining layer 116b is formed over the first lining layer 116a, and the third lining layer 116c is formed over the second lining layer 116b, and the first bulk layer 116d is formed over the third lining layer 116c to fill the trenches between the fin structures 104.

After the first bulk layer 116d is formed, the isolation structure 116 is etched back, and the mask structure 118 is formed over the isolation structure 116 in accordance with some embodiments. The mask structure 118 is configured to protect the isolation structure 116 to prevent the isolation structure 116 being etched during subsequent manufacturing processes. The mask structure 118 may include multiple layers, although they are not shown in FIG. 2C-1. In some embodiments, the mask structure 118 includes a fourth lining layer 118a formed over the first lining layer 116a, the second lining layer 116b, the third lining layer 116c, and the first bulk layer 116d and a second bulk layer 118b formed over the fourth lining layer 118a.

In some embodiments, the first, second, third and fourth lining layers 116a, 116b, 116c, and 118a and the first and second bulk layers 116d and 118b are made of silicon-containing dielectric materials, such as silicon oxide (SiO₂), silicon nitride (SiN), silicon oxynitride (SiON), silicon carbon nitride (SiCN), silicon oxycarbonitride (SiOCN), and/or oxygen-doped silicon carbonitride (Si(O) CN). In an embodiment, the first lining layer 116a and the fourth lining layer 118a are made of silicon oxide (SiOx), and the second lining layer 116b and the third lining layer 116c are made of low-k dielectric material (e.g., with a k value less than 7.9) such as silicon oxycarbonitride (SiOCN). In an embodiment, the first bulk layer 115d and the second bulk layer 118b are made of different materials and have a great difference in etching selectivity. For example, the first bulk layer 116d is made of silicon oxide (SiOx), and the second bulk layer 118b is made of silicon nitride (SiN).

The first, second, third and fourth lining layers 116a, 116b, 116c, and 118a and the first and second bulk layers 116d and 118b may be formed by performing deposition processes, such as in situ steam generation (ISSG), thermal oxidation, CVD (such as low-pressure CVD (LPCVD), plasma-enhanced CVD (PECVD), high density plasma CVD (HDP-CVD), high aspect ratio process (HARP), or flowable CVD (FCVD)), atomic layer deposition (ALD), another suitable technique, and/or a combination thereof. The etching back processes may include dry plasma etching and/or wet chemical etching.

After the isolation structure 116 and the mask structure 118 are formed, dummy gate structures 130 are formed across the fin structures 104, as shown in FIGS. 3B-1, 3B-2, 3B-3, 3B-4, and 3B-5 in accordance with some embodiments. The dummy gate structure 130 may be used to define the channel regions of the resulting semiconductor structure. The dummy gate structures 130 are longitudinally oriented along Y direction and may be formed at the location of the gate structure 170 shown in FIGS. 1A and 1B and may be replaced with the gate structures afterwards.

In some embodiments, each of the dummy gate structures 130 includes a dummy gate dielectric layer 132 and a dummy gate electrode layer 134. In some embodiments, the dummy gate dielectric layer 132 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 132 is formed using thermal oxidation, CVD, ALD, physical vapor deposition (PVD), another suitable method, or a combination thereof.

In some embodiments, the dummy gate electrode layer 134 is made of conductive material includes polycrystalline-silicon (poly-Si), poly-crystalline silicon-germanium (poly-SiGe), or a combination thereof. In some embodiments, the dummy gate electrode layer 134 is formed using CVD, PVD, or a combination thereof.

In some embodiments, a hard mask layer 137 is formed over the dummy gate electrode layer 134. In some embodiments, the hard mask layer 137 includes multiple layers, such as an oxide layer 135 and a nitride layer 136. In some embodiments, the oxide layer 135 is made of silicon oxide, and the nitride layer 136 is made of silicon nitride.

The formation of the dummy gate structures 130 may include conformally forming a dielectric material as the dummy gate dielectric layers 132. Afterwards, a conductive material may be formed over the dielectric material as the dummy gate electrode layers 134, and the hard mask layer 137 may be formed over the conductive material. Next, the dielectric material and the conductive material may be patterned through the hard mask layer 137 to form the dummy gate structures 130.

After the dummy gate structures 130 are formed, spacer layers 138, including 138a and 138b, are formed to cover the top surfaces and the sidewalls of the dummy gate structures 130 and the fin structures 104, as shown in FIGS. 3C-1, 3C-2, 3C-3, 3C-4, and 3C-5 in accordance with some embodiments. In some embodiments, the spacer layers 138a and 138b are made of different dielectric materials. The dielectric materials may include silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

After the spacer layers 138 are formed, an etching process is performed to form gate spacers 140 and fin spacers 142 with the spacer layers 138 and to form source/drain recesses 144 in the fin structures 104, as shown in FIGS. 3D-1, 3D-2, 3D-3, 3D-4, and 3D-5 in accordance with some embodiments. The gate spacers 140 may be configured to separate source/drain structures (formed afterwards) from the dummy gate structures 130, and the fin spacers 142 may be configured to confine the growth of the source/drain structures formed therein.

More specifically, the spacer layers 138 are etched to form the gate spacers 140 on opposite sidewalls of the dummy gate structures 130 and to form the fin spacers 142 covering the sidewalls of the fin structures 104 in accordance with some embodiments. In addition, the portions of the fin structures 104 not covered by the dummy gate structures 130 and the gate spacers 140 are etched to form the source/drain recesses 144 during the etching process in accordance with some embodiments. The etching process may be an anisotropic etching process, such as dry plasma etching, and the dummy gate structure 130 and the gate spacers 140 may be used as etching masks during the etching process. In some embodiments, the isolation structure 116 is protected by the mask structure 118 during the etching process, material loss in the isolation structure 116 may be prevented.

After the source/drain recesses 144 are formed, the first semiconductor material layers 106 are removed through the source/drain recesses 144, as shown in FIGS. 3E-1, 3E-2, 3E-3, 3E-4, and 3E-5 in accordance with some embodiments. In some embodiments, an etching process is performed to remove the first semiconductor layers 106, thereby forming gaps 146. The etching processes may be an isotropic etching process, such as dry chemical etching, remote plasma etching or wet chemical etching, or a combination thereof.

After the gaps 146 are formed, a dielectric layer 150 is formed, as shown in FIGS. 3F-1, 3F-2, 3F-3, 3F-4, and 3F-5 in accordance with some embodiments. More specifically, the dielectric material 150 is deposited over the semiconductor structure to fill the gaps 146 and to cover the dummy gate structures 130 and the gate spacers 140, as shown in FIGS. 3F-2, 3F-3, and 3F-4 in accordance with some embodiments. In addition, the fin spacers 142, the mask structure 118, and the source/drain recesses 144 are also covered by the dielectric layer 150, as shown in FIGS. 3F-1 and 3F-5 in accordance with some embodiments.

The dielectric layer 150 maybe a single or multiple dielectric material layers. In some embodiments, the dielectric layer 150 is made of silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O) CN). In some embodiments, the dielectric layer 150 is formed by performing a deposition process, such as ALD, CVD (such as PECVD, LPCVD or HARP), another suitable technique, or a combination thereof.

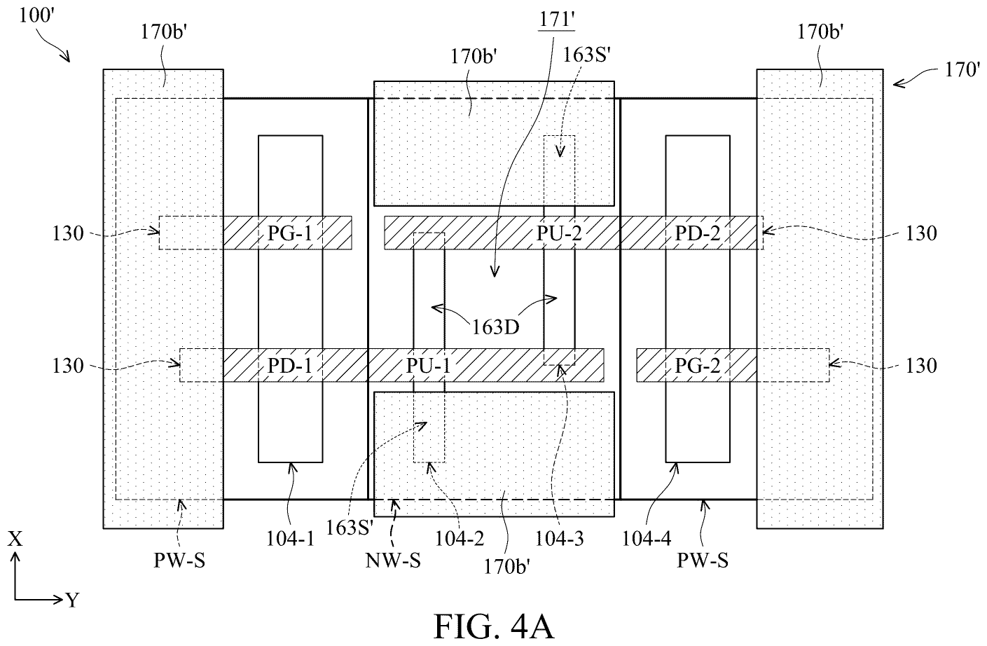

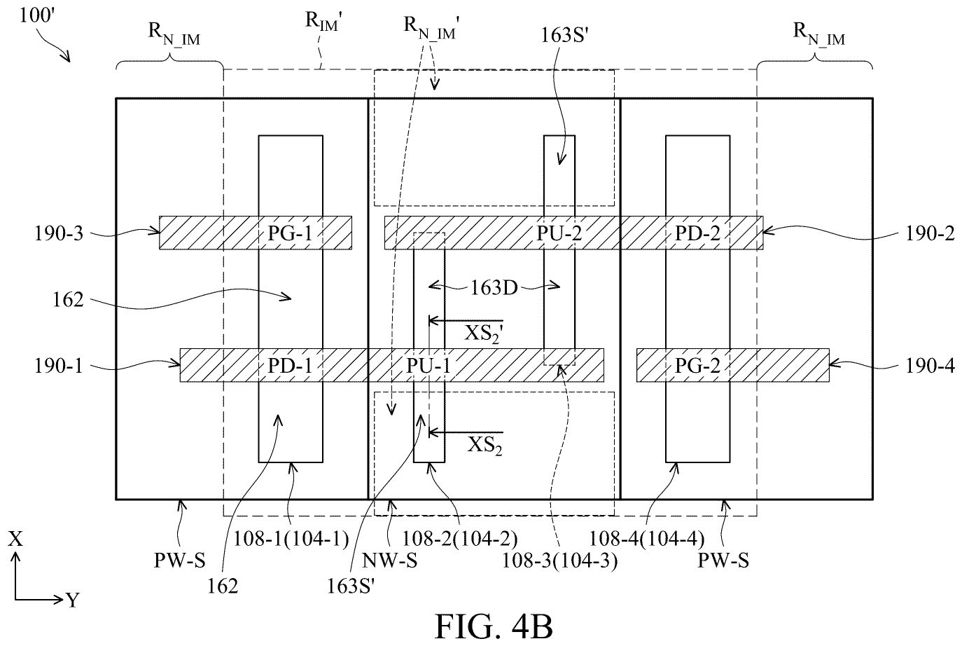

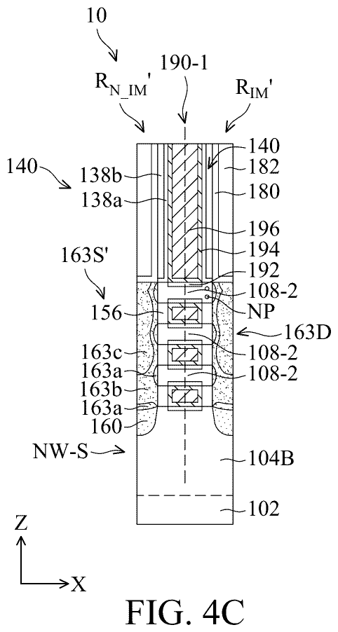

After the dielectric layer 150 is formed, an etching process is performed to form dielectric features 152 with the dielectric layer 150, as shown in FIGS. 3G-1, 3G-2, 3G-3, 3G-4, and 3G-5 in accordance with some embodiments. More specifically, an etching process may be performed to etch away the dielectric layer 150 outside the gaps 146. In some embodiments, the dielectric layer 150 in the gaps 146 are also partially etched during the etching process, so that the sidewalls of the dielectric features 152 are recessed from the sidewalls of the second semiconductor material layers 108, as shown in FIGS. 3G-3 and 3G-4 in accordance with some embodiments. That is, notches 154 are formed between the second semiconductor material layers 108 and between the bottommost one of the second semiconductor material layers 108 and the base fin structures 104B in accordance with some embodiments. In some embodiments, the etching process includes an anisotropic etching process such as dry plasma etching, an isotropic etching process such as dry chemical etching, remote plasma etching or wet chemical etching, or a combination thereof.

As shown in FIGS. 3G-3 and 3G-4, the first semiconductor layers 106 are now replaced with the dielectric features 152, and therefore the Ge diffusion due to the first semiconductor material layers 106 in subsequent manufacturing processes (e.g. the annealing processes for forming source/drain structures) may be prevented. In addition, the etching selectivity (e.g., greater than 10000) between the dielectric features 152 (e.g., SiOx) and the second semiconductor material layers 108 (e.g., Si) is much greater than the etching selectivity (e.g., about 170) between the first semiconductor material layers 106 (e.g., SiGe) and the second semiconductor material layers 108 (e.g., Si). Therefore, the loss of the channel layers (i.e. the second semiconductor material layers 108) in the following channel-releasing process can be reduced.

Afterwards, inner spacers 156 are formed in the notches 154, as shown in FIGS. 3H-1, 3H-2, 3H-3, 3H-4, and 3H-5 in accordance with some embodiments. More specifically, the inner spacer 156 are formed to abut the recessed sidewall surfaces of the dielectric features 152 in accordance with some embodiments. In some embodiments, the inner spacers 156 are located directly below the gate spacers 140. The inner spacers 156 may prevent the source/drain structures and the gate structure formed afterwards from being in direct contact with each other and may be configured to reduce the parasitic capacitance between the gate structures and the source/drain structures (i.e., Cgs and Cgd).

In some embodiments, the inner spacers 156 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O) CN). In some embodiments, the inner spacers 156 include multiple dielectric layers. In some embodiments, the inner spacers 156 and the dielectric features 152 are made of different dielectric materials, so that when the dielectric features 152 are removed during the subsequent processes, the inner spacers 156 may remain.

The inner spacers 156 may be formed by depositing a dielectric material over the semiconductor structure to overfill the notches 154 and then performing an etching back process to remove the excessing dielectric material outside the notches 154. Portions of the dielectric material left in the notches 154 then may be served as the inner spacers 156. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

After the inner spacers 156 are formed, semiconductor isolation features 160, dielectric isolation features 161, and source/drain structures 162 and 163 are formed in the source/drain recesses 144, as shown in FIGS. 31-1, 31-2, 31-3, 31-4, and 31-5 in accordance with some embodiments. More specifically, the semiconductor isolation features 160 are formed in bottom portions of the source/drain recesses 144 in accordance with some embodiments. In some embodiments, the semiconductor isolation features 160 are made of an epitaxial semiconductor material such as non-doped silicon, formed by MBE, MOCVD, or VPE, another suitable technique, or a combination thereof.

After the semiconductor isolation features 160 are formed, the dielectric isolation features 161 are formed over the semiconductor isolation features 160 over the well regions PW_S and PW_L, as shown in FIGS. 31-1, 31-3, and 31-5 in accordance with some embodiments. The dielectric isolation features 161 are configured to reduce the parasitic capacitance of the resulting n-channel transistors. In some other embodiments, the dielectric isolation features 161 may also be formed on the semiconductor isolation features 160 in the source/drain recesses 144 over the well regions NW_S and NW_L. In some embodiments, the dielectric isolation features 161 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O) CN), or high-k dielectric material (e.g., with dielectric constant greater than about 7.9) such as LaO, AlO, AION, ZrO, HfO, ZnO, ZrN, ZrAlO, TiO, TaO, YO, TaCN, or a combination thereof. In some embodiments, the dielectric isolation features 161 are deposited using a technique such as ALD, CVD (such as HDP-CVD, LPCVD or PECVD), another suitable technique, or a combination thereof, followed by an etching-back process.

Source/drain structures 162 are formed over the dielectric isolation features 161 in the source/drain recesses 144 over the well regions PW_S and PW_L, as shown in FIGS. 31-1, 31-3, and 31-5 in accordance with some embodiments. The epitaxial growth process may be MBE, MOCVD, or VPE, another suitable technique, or a combination thereof. In some embodiments, the source/drain structures 162 are in-situ doped during the epitaxial processes. In some embodiments, the source/drain structures 162 are doped with the n-type dopants during the epitaxial growth process. For example, the n-type dopants may be phosphorous (P) or arsenic (As).

For example, the source/drain structures 162 are n-type source/drain features, such as the epitaxially grown silicon phosphorous (SiP), silicon carbon (SIC), silicon phosphorous carbon (SiPC), silicon phosphorous arsenic (SiPAs), silicon arsenic (SiAs), silicon (Si), or a combination thereof doped with phosphorous and/or arsenic. In some embodiments, the concentrations of the dopant (e.g., P) in the source/drain structures 162 are in a range from about 2×10¹⁹ cm⁻³ to about 3×10²¹ cm⁻³. In some embodiments, the source/drain structures 162 may be multilayered structures, e.g., including sequentially formed layers 162a and 162b (as shown in FIG. 31-3). In some embodiments, the concentration of the dopants in the layer 162b is higher than the concentration of the dopant in the layer 162a, e.g., by 1-2 orders.

On the other hands, the source/drain structures 163 are formed over the semiconductor isolation features 160 in the source/drain recesses 144 over the well regions NW_S and NW_L, as shown in FIGS. 31-1, 31-4, and 31-5 in accordance with some embodiments. The epitaxial growth process may be MBE, MOCVD, or VPE, another suitable technique, or a combination thereof. In some embodiments, the source/drain structures 163 are in-situ doped during the epitaxial processes. In some embodiments, the source/drain structures 163 are doped with the p-type dopant during the epitaxial growth process. For example, the p-type dopant may be boron (B) or BF2.

For example, the source/drain structures 163 are p-type source/drain structure that are epitaxially grown of silicon germanium (SiGe), silicon germanium carbon (SiGeC), germanium (Ge), silicon (Si), or a combination thereof doped with boron (B). In some embodiments, the concentrations of the dopants (e.g., B) in the source/drain structures 163 are in a range from about 1×10¹⁹ cm⁻³ to about 6×10²⁰ cm⁻³. In some embodiments, the source/drain structures 163 may be multilayered structures, e.g., including sequentially formed layers 163a, 163b, and 163c (as shown in FIG. 31-4). In some embodiments, the concentration of the dopants in the layer 163c is higher than the concentration of the dopants in the layer 163b, e.g., by 1-2 orders. In an embodiment, the layer 163a is boron-doped silicon layer. In addition, in some embodiments, before the source/drain structures 163 are formed, an epitaxial (EPI) proximity push process is selectively performed on the second semiconductor layers 108.

In some embodiments, the source/drain structures 162 and the source/drain structures 163 include different types of dopants. In some embodiments, the source/drain structures 162 include N-type dopants (such as P) and the source/drain structures 163 include P-type dopants (such as B). In some embodiments, the source/drain structures 162 and the source/drain structures 163 are made of different epitaxial materials. For example, the source/drain structures 162 are N-type source/drain structures made of SiP, and the source/drain structures 163 are P-type source/drain structures made of SiGe.

The source/drain structures 162 and the source/drain structures 163 may be formed separately. For example, a patterned mask layer (such as a photoresist layer and/or a hard mask layer) may be formed to cover the semiconductor structure over the well regions NW_S and NW_L, and then the source/drain structure 162 are grown. Afterwards, the patterned mask layer may be removed. Similarly, a patterned mask layer (such as a photoresist layer and/or a hard mask layer) may be formed to cover the semiconductor structure over the well regions PW_S and PW_L, and then the source/drain structures 163 are grown. Afterward, the patterned mask layer may be removed. Once the source/drain structures 162 and 163 are formed, an annealing process may be performed to activate the dopants in the source/drain structure 162 and 163 in accordance with some embodiments. As described previously, since the first semiconductor material layers 106 have been replaced with the dielectric features 152 before the formation of the source/drain structures 162 and 163, Ge diffusion into the second semiconductor material layers 108 due to the annealing process can be prevented.

After the source/drain structures 162 and 163 are formed, a mask structure 170 is formed and an implanting process is performed afterwards, as shown in FIGS. 3J-1, 3J-2, 3J-3, 3J-4, 3J-5 in accordance with some embodiments. FIG. 3J-6 illustrates the position of the mask structure 170 over the layout of the SRAM cell 100 in accordance with some embodiments. FIG. 3J-7 illustrates the cross-sectional view of the structure shown along line YS_{SD_3J}-YS_{SD_3J}′ in FIG. 3J-6 in accordance with some embodiments. FIG. 3J-8 illustrates the cross-sectional view of the structure shown along line XS₃-XS₃′ in FIG. 3J-6 in accordance with some embodiments. FIG. 3J-9 illustrates the position of the mask structure 170 over the layout of the logic cell 200 in accordance with some embodiments. FIG. 3J-10 illustrates the cross-sectional view of the structure shown along line YL_{MG}-YL_{MG}′ in FIG. 3J-9 in accordance with some embodiments. FIG. 3J-11 illustrates the top view of the SRAM cell 100 in accordance with some embodiments.

More specifically, the mask structure 170 with openings 171 is formed over both the SRAM cell region 10 and the logic cell region 20, as shown in FIGS. 3J-6, 3J-9, and 3J-10 in accordance with some embodiments. In some embodiments, the mask structure 170 includes a material layer 170a and a mask layer 170b formed over the material layer 170a, and the mask layer 170b includes the openings 171. In some embodiments, the material layer 170a is an inorganic material or an organic material (e.g., polymer, oligomer, or monomer) formed by performing a spin-on coating process, a CVD process. In some embodiments, the material layer 170a includes multiple layers. In some embodiments, the mask layer 170b is a photoresist layer.

As shown in FIGS. 3J-1, 3J-2, 3J-3, 3J-4, 3J-6, 3J-7, and 3J-11, the source/drain structures 162 and 163 in both the well regions PW_S and NW_S in the SRAM cell region 10 are exposed by (i.e. directly under and vertically overlap) the openings 171 in accordance with some embodiments. Meanwhile, the source/drain structures 162 in the well region PW_L in the logic cell region 200 are exposed by the openings 171 while the source/drain structures 163 in the well region NW_L in the logic cell region 20 are covered by the mask layer 170b.

After the mask structure 170 is formed, the implantation process is performed to implant N-type dopants into the structures under the openings 171 in accordance with some embodiments. More specifically, the source/drain structures 162 and 163 in the SRAM cell region 10 both overlap the openings 171, and therefore the source/drain structures 162 and 163 are both doped with the N-type dopants in accordance with some embodiments. In some embodiments, the N-type dopants include phosphorous (P) or arsenic (As). In some embodiments, the concentration of the dopants used in the implantation process is in a range from about 1E15 to about 9E15. In some embodiments, the energy used in the implantation process is in a range from about 2 keV to about 6ke V.

As described previously, although the source/drain structures 163 in the SRAM cell region 10 are P-type source/drain structures, the N-type dopants are implanted into the source/drain structures 163 to weaken the resulting transistors (i.e. the PU transistors) in accordance with some embodiments. Accordingly, the overshoot issues may be prevented or reduced. In some embodiments, the source/drain structures 162 in the SRAM cell region 10 include N-type dopants but do not include P dopants, while the source/drain structures 163 in the SRAM cell region 10 include both N-type dopants and P dopants. On the other hand, the source/drain structures 163 in the logic cell region 20 are not exposed by the opening 171, and therefore the source/drain structures 163 in the logic cell region 20 include P dopants but do not include N-type dopants.

In addition, during the implantation process, in the SRAM cell region 10, the outer sidewalls of the fin spacers 142 on the sidewalls of the source/drain structures 162 and 163 under the openings 171 are also doped with the N-type dopants in accordance with some embodiments. In some embodiments, the concentration of the N-type dopants in the outer sidewalls of the fins spacers 142 is greater than the concentration of the N-type dopants in the inner sidewalls of the fin spacers 142. On the other hand, in the logic cell region 20, the outer sidewalls of the fin spacers 142 on the sidewalls of the source/drain structures 162 under the openings 171 are doped with the N-type dopants, but the outer sidewalls of the fin spacers 142 on the sidewalls of the source/drain structures 163 are not doped with the N-type dopants in accordance with some embodiments.

Furthermore, during the implantation process, in the SRAM cell region 10, the mask structure 118 around the source/drain structures 162 and 163 under the openings 171 are also doped with the N-type dopants in accordance with some embodiments. On the other hand, in the logic cell region 20, the mask structure 118 around the source/drain structures 162 under the openings 171 are doped with the N-type dopants, but the mask structure 118 around the source/drain structures 163 are not doped with the N-type dopants in accordance with some embodiments.

Moreover, during the implantation process, in the SRAM cell region 10, the portions of the gate spacers 140 and the dummy gate structures 130 over both the well regions PW_S and NW_S under the openings 171 are also doped with the N-type dopants, as shown in FIGS. 3J-1, 3J-3, 3J-4, 3J-6, and 3J-7 in accordance with some embodiments. In some embodiments, the concentration of the N-type dopants in the upper portion of the gate spacers 140 is greater than the concentration of the N-type dopants in the lower portion of the gate spacers 140. On the other hand, in the logic cell region 20, the portions of the gate spacers 140 and the dummy gate structure 130 over the well region PW_L under the openings 171 are doped with the N-type dopants, but the portions of the gate spacers 140 and the dummy gate structure 130 over the well region NW_L under the mask layer 170b are not doped with the N-type dopants, as shown in FIGS. 3J-9 and 3J-10 in accordance with some embodiments. Meanwhile, some portions of the dummy gate structure 130 in the SRAM cell region 10 are not exposed by the opening 171 in the top view and therefore are not doped with the N-type dopants during the implantation process, as shown in FIGS. 3J-6 and 3J-8 in accordance with some embodiments.

After the implantation process is performed, the mask structure 170 is removed, and a contact etch stop layer (CESL) 180 is conformally formed to cover the source/drain structures 162 and 163, and an interlayer dielectric (ILD) layer 182 is formed over the contact etch stop layers 180, as shown in FIGS. 3K-1, 3K-2, 3K-3, 3K-4, 3K-5 in accordance with some embodiments.

In some embodiments, the contact etch stop layer 180 is made of a dielectric materials, such as silicon nitride, silicon oxide, silicon oxynitride, another suitable dielectric material, or a combination thereof. The dielectric material for the contact etch stop layers 180 may be conformally deposited over the semiconductor structure by performing CVD, ALD, other application methods, or a combination thereof.

The interlayer dielectric layer 182 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 182 may be formed by chemical vapor deposition (CVD), physical vapor deposition, (PVD), atomic layer deposition (ALD), or other applicable processes. After the contact etch stop layer 180 and the interlayer dielectric layer 182 are deposited, a planarization process such as CMP or an etch-back process is performed until the dummy gate electrode layer 134 is exposed in accordance with some embodiments.

Next, dummy gate electrode layers 134 of the dummy gate structures 130 are removed to form gate trenches 184, as shown in FIGS. 3L-1, 3L-2, 3L-3, 3L-4, and 3L-5 in accordance with some embodiments. The removal process may include one or more etching processes. For example, when the dummy gate electrode layer 134 may be made of polysilicon, a wet etchant such as a tetramethylammonium hydroxide (TMAH) solution may be used to selectively remove the dummy gate electrode layer 134.

After the dummy gate electrode layers 134 are removed, the dummy gate dielectric layer 132 and the dielectric features 152 are removed to form gaps 186, as shown in FIGS. 3M-1, 3M-2, 3M-3, 3M-4, and 3M-5 in accordance with some embodiments. More specifically, the dielectric features 152 are removed, and the second semiconductor material layers 108 of the fin structures 104 are served as channel structures 108-1, 108-2, 108-3, 108-4, and 108-5 (or also called nanostructures 108-1, 108-2, 108-3, 108-4, and 108-5) in accordance with some embodiments. As shown in FIGS. 3M-2, 3M-3, and 3M-4, the channel structures 108-1, 108-2, 108-3, 108-4, and 108-5 are vertically suspended over the substrate 102 and spaced apart from each other in Z direction in accordance with some embodiments. In addition, the channel structures 108-1, 108-2, 108-3, 108-4, and 108-5 laterally extend between and interposing the source/drain structures 162 and 163 respectively in X direction in accordance with some embodiments.

The removal process may include one or more etching processes. For example, both of the dummy gate dielectric layer 132 and the dielectric features 152 may be made of oxide and may be removed using a plasma dry etching, a dry chemical etching, and/or a wet etching. As described previously, since the dielectric features 152 and the second semiconductor material layers 108 have relatively high etching selectivity (e.g. compare to the first semiconductor material layers 106 and the second semiconductor material layers 108), the dielectric features 152 may be fully removed without removing the second semiconductor material layers 108 too much.

Next, the gate structures 190, including 190-1, 190-2, 190-3, 190-4, and 190-5, are formed in the gate trenches 184 and the gaps 186, as shown in FIGS. 3N-1, 3N-2, 3N-3, 3N-4, and 3N-5 in accordance with some embodiments. In some embodiments, the gate structures 190 wraps around the channel structures 108-1, 108-2, 108-3, 108-4, and 108-5 and extends lengthwise in Y direction. In some embodiments, the gate structure 190 includes an interfacial layer 192, a gate dielectric layer 194, and a gate stack layer 196.

The interfacial layer 192 may be used to improve the interfaces between the channel structures 108-1, 108-2, 108-3, 108-4, and 108-5 and dielectric layers formed afterwards. In addition, the interfacial layer 192 may be able to help suppressing the mobility degradation of charge carries in the channel structures 108 that serve as channel regions of the transistors. In some embodiments, the interfacial layer 192 is an oxide layer formed by performing a thermal process. In some embodiments, the interfacial layer 192 has a thickness in a range from about 0.5 nm to about 1.5 nm.

After the interfacial layer 192 is formed, the gate dielectric layer 194 is conformally formed to cover the interfacial layers 192 and the bottom surface and the sidewalls of the gate trenches 184 and the gaps 186 in accordance with some embodiments. In some embodiments, the gate dielectric layer 194 is made of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, La₂O₃-Al₂O₃ or LaO, other applicable high-k dielectric materials, or a combination thereof. In some embodiments, the gate dielectric layer 194 is formed using CVD, ALD, other applicable methods, or a combination thereof. In some embodiments, the gate dielectric layer 194 has a thickness in a range from about 1 nm to about 2 nm.

After the gate dielectric layer 194 is formed, the gate stack layer 196 is formed over the gate dielectric layer 194 in accordance with some embodiments. In some embodiments, the gate stack layer 196 includes multiple layers. In some embodiments, the gate stack layer 196 includes a work function metal layer. In some embodiments, the work function layers over the well regions PW_S and NW_S are made of different materials, and the work function layers over the well regions PW_L and NW_L are made of different materials. In some embodiments, the work function metal layer is made of titanium nitride, tantalum nitride, tungsten nitride, tantalum, or the like.

In some embodiments, the gate stack layer 196 includes a gate filling layer formed over the work functional layer. In some embodiments, the gate filling layer is made of a conductive material, such as tungsten, titanium, tantalum, cobalt, copper, or the like. In some embodiments, the gate filling layer is formed using CVD, ALD, electroplating, another applicable method, or a combination thereof. In some embodiments, a polishing process, such as a CMP process, is performed after depositing the gate dielectric layer 194 and the gate stack layer 196. Although not shown in the figures, the gate structures 190 may include different regions made of different materials. For example, the regions of the gate structures 190 formed over the P-type well regions may be different from those formed over the N-type well regions. In addition, some gate isolation structures may be formed to divide the gate structures 190 into isolated portions.

FIG. 3N-6 illustrates the layout of the SRAM cell 100 in accordance with some embodiments. FIG. 3N-7 illustrates the layout of the logic cell 200 in accordance with some embodiments. FIG. 3N-8 illustrates the cross-sectional view of the structure shown along line XS₃-XS₃′ in FIG. 3N-6 in accordance with some embodiments. FIG. 3N-9 illustrates the cross-sectional view of the structure shown along line YL_{MG}-YL_{MG}′ in FIG. 3N-7 in accordance with some embodiments.

As described previously, the semiconductor device includes the SRAM cell 100 and the logic cell 200 in accordance with some embodiments. In some embodiments, the SRAM cell 100 includes the transistors PD-1, PG-1, PD-2, and PG-2 formed in the well regions PW-S and the transistors PU-1 and PU-2 formed in the well regions NW_S, as shown in FIGS. 3N-1, 3N-2, 3N-3, 3N-4, 3N-6 and 3N-8. Each of the transistors PD-1, PG-1, PD-2, and PG-2 includes the channel structures 108 (e.g. 108-1 and 108-4) and the source/drain structures 162 attached to the opposite sides of the channel structures 108 in accordance with some embodiments. Similarly, each of the transistors PU-1 and PU-2 includes the channel structures 108 (e.g. 108-2 and 108-3) and the source/drain structures 163 attached to the opposite sides of the channel structures 108 in accordance with some embodiments.

In some embodiments, a first region of the gate structure 190-1 wraps around the channel structures 108-1 and a second region of the gate structure 190-1 wraps around the channel structures 108-2. In addition, the gate structure 190-1 further covers an end of the channel structures 108-3 in accordance with some embodiments. In some embodiments, the gate structure 190-2 wraps around the channel structures 108-3 and 108-4 and covers an end of the channel structures 108-2. In some embodiments, the gate structure 190-3 wraps around the channel structures 108-1. In some embodiments, the gate structure 190-4 wraps around the channel structures 108-4.

In some embodiments, the logic cell 200 includes the transistor T1 formed in the well regions PW-L and the transistor T2 formed in the well regions NW_L, as shown in FIGS. 3N-5, 3N-7, and 3N-9. The transistor T1 includes the channel structures 108-5 and the source/drain structures 162 attached to the opposite sides of the channel structures 108-5 in accordance with some embodiments. Similarly, the transistor T2 includes the channel structures 108-6 and the source/drain structures 163 attached to the opposite sides of the channel structures 108-6 in accordance with some embodiments. In some embodiments, the gate structure 190-5 wraps around the channel structures 108-5 and 108-6.

As described previously, an implantation process is performed after the mask structure 170 with the opening 171 is formed, the SRAM cell 100 and the logic cell 200 therefore include implanted regions R_{IM} and non-implanted regions R_{N_IM} in accordance with some embodiments. As shown in FIG. 3N-6, the source/drain structures 162 and 163 in the SRAM cell 100 are all in the implanted region R_{IM} and therefore all doped with the N-type dopants in accordance with some embodiments. On the other hand, the source/drain structures 162 in the logic cell 200 are formed in the implanted region R_{IM} and are therefore doped with the N-type dopants, but the source/drain structures 163 in the logic cell 200 are formed in the non-implanted regions R_{N_IM} and therefore are not doped with the N-type dopants, as shown in FIG. 3N-7 in accordance with some embodiments. In some embodiments, the N-type dopants also diffuse into the channel structures 108-1, 108-2, 108-3, 108-4, and 108-5. In some embodiments, the concentration of the N-type dopants in the topmost one of the channel structures 108-1, 108-2, 108-3, 108-4, and 108-5 is greater than the concentration of the N-type dopants in the bottommost one of the channel structures 108-1, 108-2, 108-3, 108-4, and 108-5.

FIG. 3N-10 illustrates an enlarged structure of a region R_{3N-1} shown in FIG. 3N-1 in accordance with some embodiments. FIG. 3N-11 illustrates an enlarged structure of a region R_{3N-5} shown in FIG. 3N-5 in accordance with some embodiments. As described previously the outer sidewalls of the fin spacers 142 on the sidewalls of the source/drain structures 162 and 163 in the implanted region R_{IM} are also doped with the N-type dopants NP, as shown in FIG. 3N-10 in accordance with some embodiments. On the other hand, in the logic cell region 20, the outer sidewalls of the fin spacers 142 on the sidewalls of the source/drain structures 162 in the implanted region R_{IM} are doped with the N-type dopants, but the outer sidewalls of the fin spacers 142 on the sidewalls of the source/drain structures 163 in the non-implanted regions R_{N_IM} are not doped with the N-type dopants, as shown in FIG. 3N-11 in accordance with some embodiments.

Furthermore, in the SRAM cell region 10, the mask structure 118 around the source/drain structures 162 and 163 in the implanted region R_{IM} are also doped with the N-type dopants, as shown in FIG. 3N-10 in accordance with some embodiments. On the other hand, in the logic cell region 20, the mask structure 118 around the source/drain structures 162 in the implanted region R_{IM} are doped with the N-type dopants, but the mask structure 118 around the source/drain structures 163 in the non-implanted regions R_{N_IM} are not doped with the N-type dopants, as shown in FIG. 3N-11 in accordance with some embodiments.

FIG. 3N-12 illustrates an enlarged structure of a region R_{3N-3} shown in FIG. 3N-3 in accordance with some embodiments. As described previously, in the SRAM cell region 10, the portions of the gate spacers 140 over both the well regions PW_S and NW_S in the implanted region R_{IM} are also doped with the N-type dopants, as shown in FIG. 3N-12 in accordance with some embodiments. On the other hand, in the logic cell region 20, the portions of the gate spacers 140 over the well region PW_S in the implanted region R_{IM} are doped with the N-type dopants, but the portions of the gate spacers 140 over the well region NW_L in the non-implanted regions R_{N_IM} are not doped with the N-type dopants in accordance with some embodiments. In addition, some portions of the gate spacers 140 in the SRAM cell region 10 are also in the non-implanted regions R_{N_IM} and therefore are not doped with the N-type dopants, as shown in FIGS. 3N-8 in accordance with some embodiments.

In some other embodiments, the mask structure for implanting the N-type dopants may have different design. FIG. 4A illustrates a position of a mask structure 170′ for forming a SRAM cell 100′ in accordance with some embodiments. FIG. 4B illustrates the layout of the SRAM cell 100′ in accordance with some embodiments. FIG. 4C illustrates a cross-sectional view of the SRAM cell 100′ along line XS₂-XS₂′ in FIG. 4B in accordance with some embodiments.

More specifically, the semiconductor device may include the SRAM cell 100′ and the logic cell 200 described previously. The materials and processes for manufacturing the SRAM cell 100′ are similar to, or the same as, those for manufacturing the SRAM cell 100 described previously, except an opening 171′ of a mask structure 170′ used for forming the SRAM cell 100′ does not expose the source structures of the transistors PU-1 and PU-2, as shown in FIG. 4A in accordance with some embodiments. For example, the processes shown in FIGS. 1A to 31-5 may be performed, and the mask structure 170 shown in FIGS. 3J-1 to 3J-11 may be replaced with the mask structure 170′. Afterwards, the processes shown in FIGS. 3K-1 to 3N-12 may be performed to form the SRAM cell 100′ and the logic cell 200.

As shown in FIG. 4A, mask layers 170b′ of the mask structure 170′ covers source structures 163S′ of the transistors PU-1 and PU-2, while the opening 171′ of the mask structure 170′ exposed drain structures 163D of the transistors PU-1 and PU-2 in accordance with some embodiments. Accordingly, the resulting SRAM cell 100′ inclues an non-implanted regions R_{N_IM}′ over the source structures 163′ of the transistors PU-1 and PU-2 and an implanted regions R_{IM}′ in the top view, as shown in FIG. 4B in accordance with some embodiments.

As shown in FIG. 4C, the channel structures 108-2 is attached to a drain structure 163D in the implanted regions R_{IM}′ and a source structure 163S′ in the non-implanted regions R_{N_IM}′ in accordance with some embodiments. Therefore, the drain structure 163D are implanted with the N-type dopants during the implantation process but the source structure 163S′ are not implanted with the N-type dopants in accordance with some embodiments. That is, the channel structures 108-2 are partially located in the non-implanted regions R_{N_IM}′ and partially located in the implanted regions R_{IM}′ in accordance with some embodiments. Similarly, channel structures 108-3 are also partially located in the non-implanted regions R_{N_IM}′ and partially located in the implanted regions R_{IM}′ and are attached to the drain structure 163D in the implanted regions R_{IM}′ and the source structure 163S′ in the non-implanted regions R_{N_IM}′ in accordance with some embodiments.

In some embodiments, the N-type dopants in the drain structure 163D are diffused into the channel structures 108-2 and 108-3. In some embodiments, the concentration of the N-type dopants in the topmost one of the channel structures 108-2 and 108-3 is greater than the concentration of the N-type dopants in the bottommost one of the channel structures 108-2 and 108-3. In some embodiments, the topmost one of the channel structures 108-2 and 108-3 has a first end attached to the drain structure 163D and a second end attached to source structure 163S′, and the concentration of the N-type dopants at the first end is greater than the concentration of the N-type dopants at the second end.

In addition, the gate structure 190-1 is formed to wrap around the channel structures 108-2, and a first portion of the gate spacers 140 formed on a first sidewall of the gate structure 190-1 is located in the implanted regions R_{IM}′, while a second portion of the gate spacers 140 formed on a second sidewall of the gate structure 190-1 is located in the non-implanted regions R_{N_IM}′, as shown in FIG. 4C in accordance with some embodiments. Therefore, the first portion of the gate spacers 140 is doped with the N-type dopants while the second portion of the gate spacers 140 is not doped with the N-type dopants in accordance with some embodiments. The gate spacers 140 formed on opposite sidewalls of the gate structure 190-2 may have similar structure as described above. Other elements and structures in the SRAM cell 100′ and the logic cell 200 may be similar to, or the same as, those shown in FIGS. 3N-1 to 3N-12 and therefore are not repeated herein.

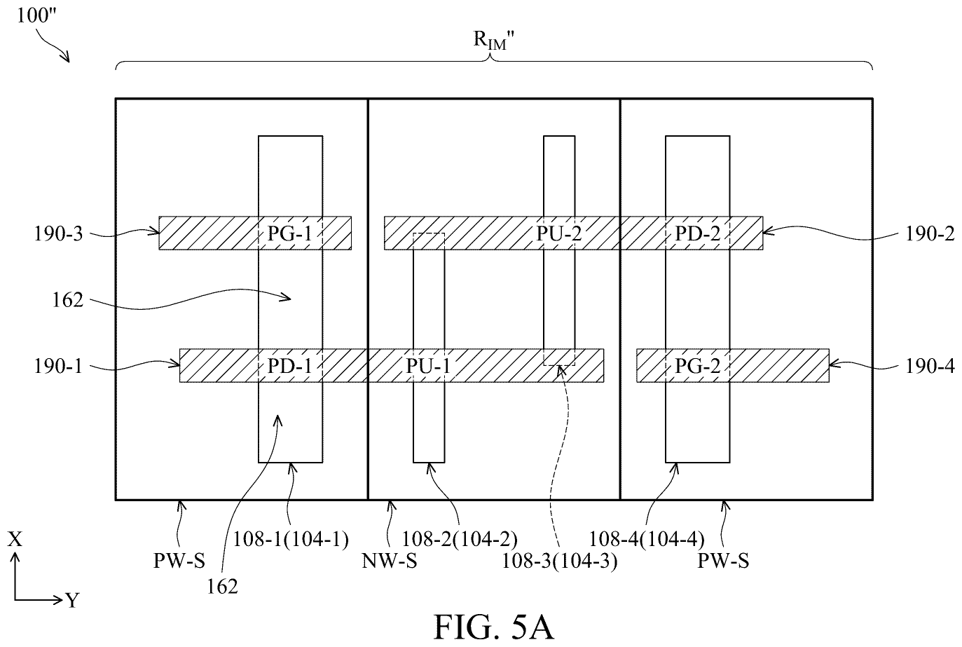

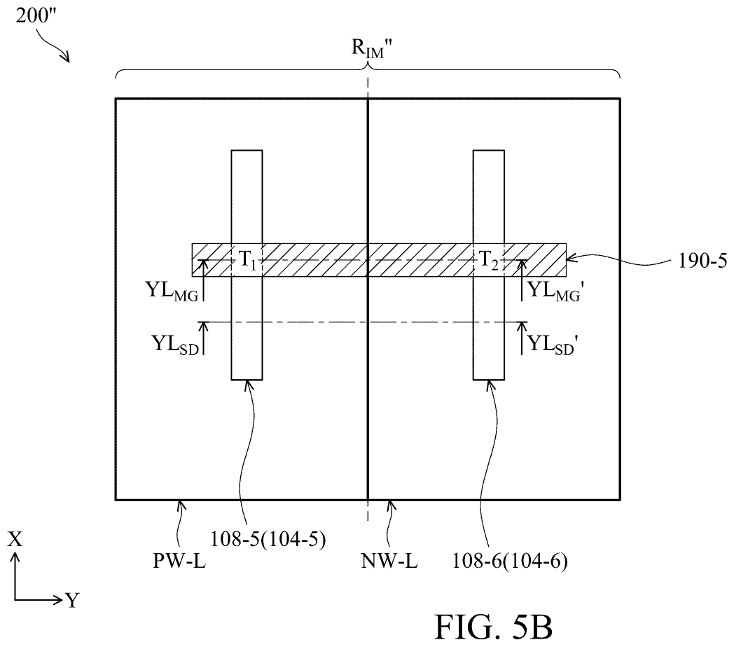

In some other embodiments, no mask structure is used during the manufacturing processes for forming the semiconductor device. FIG. 5A illustrates a layout of a SRAM cell 100″ in accordance with some embodiments. FIG. 5B illustrates a layout of a logic cell 200″ in accordance with some embodiments.

More specifically, the semiconductor device may include the SRAM cell 100″ and the logic cell 200″. The materials and processes for manufacturing the SRAM cell 100″ and the logic cell 200″ are similar to, or the same as, those for manufacturing the SRAM cell 100 and the logic cell 200 described previously, except no mask structure is used before performing the implantation process in accordance with some embodiments. That is, the processes shown in FIGS. 1A to 31-5 may be performed, and then the implantation process is performed without applying any mask structure. Afterwards, the processes shown in FIGS. 3K-1 to 3N-12 may be performed to form the SRAM cell 100″ and the logic cell 200″. That is, all the source/drain structure 162 and 163 in the SRAM cell 100″ and the logic cell 200″ are located inside implanted regions R_{IM}″ and therefore are all doped with the N-type dopants, as shown in FIGS. 5A and 5B in accordance with some embodiments.

Generally, channel structures 108 (e.g. nanostructures) are form by forming a semiconductor stack including the first semiconductor material layers 106 and the second semiconductor material layers 108 alternately stacked. The first semiconductor material layers 106 serve as sacrificial layers during the manufacturing processes, and the second semiconductor material layers 108 serve as the channel structures in the resulting transistors. However, during the manufacturing processes, such as thermal processes, Ge in the first semiconductor material layers 106 may diffuse into the second semiconductor material layers 108, which may result in undermining the performance of the resulting devices. Accordingly, in the embodiments described above, the first semiconductor material layers 106 are replaced with dielectric features 152 before the source/drain structures 162 and 163 are for, so that the issues of Ge diffusion may be reduced or avoided.

On the other hand, since the tensile stress provided by the first semiconductor material layers 106 no longer exist, the performance of the PMOS transistor may become stronger (e.g. +30%) and the performance of the NMOS transistor may become weaker (e.g. −4%) due to the stress change. This may be harmful for Write Vmin (WVmin).

Therefore, an implantation process is performed to implant N-type dopants into the source/drain structures 163 (i.e. P-type source/drain structures) in PMOS transistors in accordance with some embodiments. For example, the source/drain structures 163 in the pull-up transistors PU-1 and PU-2 in the SRAM cells 100, 100′, and 100″ are at least partially doped with the N-type dopants. As a result, Vt (Threshold Voltage)/Isat (Saturation Current) of the pull-up transistors PU-1 and PU-2 are modified, so that the overshoot and unbalance issues may be reduced. In addition, in some embodiments, the source/drain structures 163 in the logic cell 200″ are also doped with the N-type dopants, so that the ring oscillator (RO) unbalance at NFET and PFET may also be reduced, and the power efficiency of the resulting devices may be improved.

It should be appreciated that the elements shown in the SRAM cells 100, 100′, 100″ and the logic cells 200 and 200″ may be combined and/or exchanged. In addition, it should be noted that same elements in FIGS. 1A to 5B may be designated by the same numerals and may include materials that are the same or similar and may be formed by processes that are the same or similar; therefore such redundant details are omitted in the interests of brevity. In addition, although FIGS. 1A to 5B are described in relation to the method, it will be appreciated that the structures disclosed in FIGS. 1A to 5B are not limited to the method but may stand alone as structures independent of the method. Similarly, the methods shown in FIGS. 1A to 5B are not limited to the disclosed structures but may stand alone independent of the structures. Furthermore, the channel structures (e.g. the nanostructures) described above may include nanowires, nanosheets, or other applicable nanostructures in accordance with some embodiments.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments for forming semiconductor structures may be provided. The semiconductor structure may include a first transistor formed over a first well region and a second transistor formed over a second well region. The first transistor includes first channel structures and a first source/drain structure attached to the first channel structures and the second transistor includes second channel structures and a second source/drain structure attached to the second channel structures. During the formation of the first transistor and the second transistor, an implantation process is performed to implant first type of dopants into both the first source/drain structure and the second source/drain structure, so that the performance of the first transistor and the second transistor may be more balance.

Semiconductor structures and method for forming the same are provided. The semiconductor structure includes a first transistor formed in a first well region. The first transistor includes first channel structures, a first source/drain structure attached to the first channel structures, and a first region of a first gate structure wrapping around the first channel structures. The semiconductor structure further includes a second transistor formed in a second well region. The second transistor includes second channel structures, a second source/drain structure attached to the second channel structures, and a second region of the first gate structure wrapping around the second channel structures. In addition, the first well region has a first conductivity type and the second well region has a second conductivity type that is different from the first conductivity type, and the first source/drain structure and the second source/drain structure are both doped with first dopants of the second conductivity type.

Semiconductor structures and method for forming the same are provided. The method for manufacturing a semiconductor structure includes alternately stacking first semiconductor material layers and second semiconductor material to form a semiconductor stack over a first well region and a second well region of a substrate and patterning the semiconductor stack to form a first fin structure in the first well region and a second fin structure in the second well region. The method further includes forming a first source/drain recess in the first fin structure and a second source/drain recess in the second fin structure and replacing the first semiconductor material layers of the first fin structure and the first semiconductor material layers of the second fin structure with dielectric features. The method further includes forming a first source/drain structure in the first source/drain recess and a second source/drain structure in the second source/drain recess and implanting first dopants in both the first source/drain structure and the second source/drain structure. The method further includes removing the dielectric features and forming a gate structure wrapping around the second semiconductor material layers of the first fin structure and the second semiconductor material layers of the second fin structure.

Semiconductor structures and method for forming the same are provided. The method for forming the semiconductor structure includes forming a first fin structure and a second fin structure in a static random access memory cell region. The first fin structure includes sacrificial semiconductor layers and first channel layers alternately stacked, and the second fin structure includes sacrificial semiconductor layers and second channel layers alternately stacked. The method further includes removing the sacrificial semiconductor layers of the first fin structure and the second fin structure to form first gaps and second gaps, respectively and forming first dielectric features in the first gaps and second dielectric features in the second gaps. The method further includes forming an N-type source/drain structure attached to the first channel layers and a P-type source/drain structure attached to the second channel layers and implanting N-type dopants in both the N-type source/drain structure and the P-type source/drain structure. The method further includes removing the first dielectric features and the second dielectric features and forming a gate structure wrapping around the first channel layers and the second channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor formed in a first well region, wherein the first transistor comprises:
first channel structures;
a first source/drain structure attached to the first channel structures in a first direction; and
a first region of a first gate structure wrapping around the first channel structures, wherein the first gate structure extends in a second direction that is different from the first direction; and
a second transistor formed in a second well region, wherein the second transistor comprises:
second channel structures spaced apart from the first channel structures in the second direction;
a second source/drain structure attached to the second channel structures in the first direction; and
a second region of the first gate structure wrapping around the second channel structures,
wherein the first well region has a first conductivity type and the second well region has a second conductivity type that is different from the first conductivity type, and the first source/drain structure and the second source/drain structure are both doped with first dopants of the second conductivity type.

2. The semiconductor structure as claimed in claim 1, wherein the first transistor comprises a third source/drain structure and the second transistor comprises a fourth source/drain structure spaced apart from the third source/drain structure in the second direction, wherein the first dopants are also doped in the third source/drain structure but not in the fourth source/drain structure.

3. The semiconductor structure as claimed in claim 2, further comprising:
a third transistor formed in the second well region, wherein the third transistor comprises:
third channel structures spaced apart from the second channel structures in the second direction;
a fifth source/drain structure and a sixth source/drain structure attached to opposite sides of the third channel structures in the first direction; and
a second gate structure wrapping around the third channel structures,
wherein at least one of the fifth source/drain structure and the sixth source/drain structure is doped with the first dopants.

4. The semiconductor structure as claimed in claim 3, wherein the second gate structure abuts the second channel structures.

5. The semiconductor structure as claimed in claim 1, wherein the second source structure further comprises second dopants of the first conductivity type.

6. The semiconductor structure as claimed in claim 1, wherein the first transistor is a pull-down transistor and the second transistor is a pull-up transistor formed in a static random access memory cell region.

7. The semiconductor structure as claimed in claim 6, further comprising:
a third transistor formed in a third well region in a logic region, wherein the third transistor comprises:
third channel structures; and
a third source/drain structure attached to the third channel structures; and
a fourth transistor formed in a fourth well region in the logic region, wherein the fourth transistor comprises:
fourth channel structures; and
a fourth source/drain structure attached to the fourth channel structures,
wherein the third source/drain structure is doped with both the first dopants and second dopants of the first conductivity type while the fourth source/drain structure is doped with the second dopants but not the first dopants.

8. The semiconductor structure as claimed in claim 1, further comprising:
gate spacers formed on sidewalls of the first gate structure; and
fin spacers formed on sidewalls of the first source/drain structure and the second source/drain structure,
wherein the gate spacers and the fin spacers are doped with the first dopants.

9. A method for manufacturing a semiconductor structure, comprising:
alternately stacking first semiconductor material layers and second semiconductor material to form a semiconductor stack over a first well region and a second well region of a substrate;
patterning the semiconductor stack to form a first fin structure in the first well region and a second fin structure in the second well region;
forming a first source/drain recess in the first fin structure and a second source/drain recess in the second fin structure;
replacing the first semiconductor material layers of the first fin structure and the first semiconductor material layers of the second fin structure with dielectric features;
forming a first source/drain structure in the first source/drain recess and a second source/drain structure in the second source/drain recess;
implanting first dopants in both the first source/drain structure and the second source/drain structure;
removing the dielectric features; and
forming a gate structure wrapping around the second semiconductor material layers of the first fin structure and the second semiconductor material layers of the second fin structure.

10. The method for manufacturing the semiconductor structure as claimed in claim 9, wherein the first dopants are N-type dopants.

11. The method for manufacturing the semiconductor structure as claimed in claim 10, wherein the first well region is a P-type well region, and the second well region is an N-type well region.

12. The method for manufacturing the semiconductor structure as claimed in claim 9, further comprising:
forming a dummy gate structure across the first fin structure and the second fin structure before forming the first source/drain recess and the second source/drain recess, wherein the first dopants are implanted into the dummy gate structure.

13. The method for manufacturing the semiconductor structure as claimed in claim 9, further comprising:
forming a dummy gate structure across the first fin structure and the second fin structure before forming the first source/drain recess and the second source/drain recess; and
forming gate spacers over sidewalls of the dummy gate structure, wherein the first dopants are implanted into the gate spacers.

14. The method for manufacturing the semiconductor structure as claimed in claim 9, further comprising:
forming an isolation structure around the first fin structure and the second fin structure;
forming a mask structure over the isolation structure, wherein the first dopants are implanted into the mask structure.

15. A method for forming a semiconductor structure, comprising:
forming a first fin structure and a second fin structure in a static random access memory cell region, wherein the first fin structure comprises sacrificial semiconductor layers and first channel layers alternately stacked, and the second fin structure comprises sacrificial semiconductor layers and second channel layers alternately stacked;
removing the sacrificial semiconductor layers of the first fin structure and the second fin structure to form first gaps and second gaps, respectively;
forming first dielectric features in the first gaps and second dielectric features (152) in the second gaps;
forming an N-type source/drain structure attached to the first channel layers and a P-type source/drain structure attached to the second channel layers;
implanting N-type dopants in both the N-type source/drain structure and the P-type source/drain structure;
removing the first dielectric features and the second dielectric features; and
forming a gate structure wrapping around the first channel layers and the second channel layers.

16. The method for manufacturing the semiconductor structure as claimed in claim 15, further comprising:
forming a mask layer having an opening before implanting the N-type dopants in both the N-type source/drain structure and the P-type source/drain structure, wherein the N-type source/drain structure and the P-type source/drain structure are both vertically overlapping the opening.

17. The method for manufacturing the semiconductor structure as claimed in claim 16, wherein the second fin structure is partially under the opening while being partially covered by the mask layer in a top view.

18. The method for manufacturing the semiconductor structure as claimed in claim 15, further comprising:
forming a dummy gate structure across the first fin structure and the second fin structure;
forming a dielectric layer in the first gaps and the second gaps and over a top surface of the dummy gate structure after removing the sacrificial semiconductor layers of the first fin structure and the second fin structure; and
partially removing the dielectric layer to form the first dielectric features and the second dielectric features from the dielectric layer.

19. The method for manufacturing the semiconductor structure as claimed in claim 18, further comprising:
forming gate spacers on sidewalls of the dummy gate structure, wherein the dielectric layer covers sidewalls and top surfaces of the gate spacers.

20. The method for manufacturing the semiconductor structure as claimed in claim 19, wherein the gate spacers are doped with the N-type dopants.
